(19) United States
(12) Patent Application Publication
(10) Pub. No.: US 2005/0142739 A1
(43) Pub. Date: Jun. 30, 2005

(54) Probe arrays and method for making

(75) Inventors: Ananda H. Kumar, Fremont, CA (US); Ezekiel J. J. Kruglick, San Diego, CA (US); Adam L. Cohen, Los Angeles, CA (US); Kieun Kim, Pasadena, CA (US); Gang Zhang, Monterey Park, CA (US)

Correspondence Address: MICROFABRICA INC.;DENNIS R. SMALLEY, 1103 W. ISABEL ST., BURBANK, CA, 91506, US

(73) Assignee: Microfabrica Inc.

(21) Appl. No.: 11/028,958

(22) Filed: Jan. 3, 2005

Related U.S. Application Data
(63) Continuation-in-part of application No. 10/772,943, filed on Feb. 4, 2004.
(63) Continuation-in-part of application No. 10/949,738, filed on Sep. 24, 2004.
(63) Continuation-in-part of application No. 10/434,493, filed on May 7, 2003.
Application No. 10/949,738 is a continuation-in-part of application No. 60/506,015, filed on Sep. 24, 2003.
Application No. 10/949,738 is a continuation-in-part of application No. 10/772,943, filed on Feb. 4, 2004.
(63) Continuation-in-part of application No. 10/434,493, filed on May 7, 2003.
(60) Provisional application No. 60/533,947, filed on Dec. 31, 2003.
(60) Provisional application No. 60/533,933, filed on Dec. 31, 2003.
(60) Provisional application No. 60/536,865, filed on Jan. 15, 2004.
(60) Provisional application No. 60/540,511, filed on Jan. 29, 2004.
(60) Provisional application No. 60/533,933, filed on Dec. 31, 2003.
(60) Provisional application No. 60/536,865, filed on Jan. 15, 2004.
(60) Provisional application No. 60/445,186, filed on Feb. 4, 2003.
(60) Provisional application No. 60/506,015, filed on Sep. 24, 2003.
(60) Provisional application No. 60/533,933, filed on Dec. 31, 2003.
(60) Provisional application No. 60/536,865, filed on Jan. 15, 2004.
(60) Provisional application No. 60/379,177, filed on May 7, 2002.
(60) Provisional application No. 60/442,656, filed on Jan. 23, 2003.

(51) Int. Cl. H01L 21/8242

(52) U.S. Cl. 438/254

(57) ABSTRACT

Embodiments of invention are directed to the formation of microprobes (i.e. compliant electrical or electronic contact elements) on a temporary substrate, dicing individual probe arrays, and then transferring the arrays to space transformers or other permanent substrates.

### RELATED APPLICATIONS

This application claims benefit of U.S. App. Nos. 60/533,947, 60/533,933, 60/536,865, and 60/540,511. This application is a continuation in part of U.S. application Ser. Nos. 10/772,943, 10/949,738, and 10/434,493. The '738 application claims benefit of U.S. App. Nos.: 60/506,015; 60/533,933; and 60/536,865. Furthermore the '738 application is a CIP of U.S. application Ser. No. 10/772,943 which in turn claims benefit to U.S. App. Nos.: 60/445,186; 60/506,015; 60/533,933, and 60/536,865. The '493 application claims benefit of U.S. App. Nos. 60/379,177, and 60/442,656. All of the above applications are incorporated herein by reference.

### FIELD OF THE INVENTION

The present invention relates generally to the field of microelectronic probes (e.g. a microscale or mesoscale interface structures for transferring electric signals between a first circuit or circuit element and a second circuit or circuit element) and electrochemical fabrication processes for producing such probes.

### BACKGROUND OF THE INVENTION

A technique for forming three-dimensional structures (e.g. parts, components, devices, and the like) from a plurality of adhered layers was invented by Adam L. Cohen and is known as Electrochemical Fabrication. It is being commercially pursued by Microfabrica Inc. (formerly MEMGen® Corporation) of Burbank, Calif. under the name EFAB™. This technique was described in U.S. Pat. No. 6,027,630, issued on Feb. 22, 2000. This electrochemical deposition technique allows the selective deposition of a material using a unique masking technique that involves the use of a mask that includes patterned conformable material on a support structure that is independent of the substrate onto which plating will occur. When desiring to perform an electrodeposition using the mask, the conformable portion of the mask is brought into contact with a substrate while in the presence of a plating solution such that the contact of the conformable portion of the mask to the substrate inhibits deposition at selected locations. For convenience, these masks might be generically called conformable contact masks; the masking technique may be generically called a conformable contact mask plating process. More specifically, in the terminology of Microfabrica Inc. (formerly MEMGen® Corporation) of Burbank, Calif. such masks have come to be known as INSTANT MASKS™ and the process known as INSTANT MASKING™ or INSTANT MASK™ plating. Selective depositions using conformable contact mask plating may be used to form single layers of material or may be used to form multi-layer structures. The teachings of the '630 patent are hereby incorporated herein by reference as if set forth in full herein. Since the filing of the patent application that led to the above noted patent, various papers about conformable contact mask plating (i.e. INSTANT MASKING) and electrochemical fabrication have been published:
(1) A. Cohen, G. Zhang, F. Tseng, F. Mansfeld, U. Frodis and P. Will, “EFAB: Batch production of functional, fully-dense metal parts with micro-scale features”, Proc. 9th Solid Freeform Fabrication, The University of Texas at Austin, p 161, Aug. 1998.
(2) A. Cohen, G. Zhang, F. Tseng, F. Mansfeld, U. Frodis and P. Will, “EFAB: Rapid, Low-Cost Desktop Micromachining of High Aspect Ratio True 3-D MEMS”, Proc. 12th IEEE Micro Electro Mechanical Systems Workshop, IEEE, p 244, January 1999.
(3) A. Cohen, “3-D Micromachining by Electrochemical Fabrication”, Micromachine Devices, March 1999.
(4) G. Zhang, A. Cohen, U. Frodis, F. Tseng, F. Mansfeld, and P. Will, “EFAB: Rapid Desktop Manufacturing of True 3-D Microstructures”, Proc. 2nd International Conference on Integrated MicroNanotechnology for Space Applications, The Aerospace Co., Apr. 1999.
(5) F. Tseng, U. Frodis, G. Zhang, A. Cohen, F. Mansfeld, and P. Will, “EFAB: High Aspect Ratio, Arbitrary 3-D Metal Microstructures using a Low-Cost Automated Batch Process”, 3rd International Workshop on High Aspect Ratio MicroStructure Technology (HARMST'99), June 1999.
(6) A. Cohen, U. Frodis, F. Tseng, G. Zhang, F. Mansfeld, and P. Will, “EFAB: Low-Cost, Automated Electrochemical Batch Fabrication of Arbitrary 3-D Microstructures”, Micromachining and Microfabrication Process Technology, SPIE 1999 Symposium on Micromachining and Microfabrication, September 1999.
(7) F. Tseng, G. Zhang, U. Frodis, A. Cohen, F. Mansfeld, and P. Will, “EFAB: High Aspect Ratio, Arbitrary 3-D Metal Microstructures using a Low-Cost Automated Batch Process”, MEMS Symposium, ASME 1999 International Mechanical Engineering Congress and Exposition, November, 1999.
(8) A. Cohen, “Electrochemical Fabrication (EFABTM)”, Chapter 19 of The MEMS Handbook, edited by Mohamed Gad-EI-Hak, CRC Press, 2002.
(9) Microfabrication—Rapid Prototyping's Killer Application”, pages 1-5 of the Rapid Prototyping Report, CAD/CAM Publishing, Inc., June 1999.

The disclosures of these nine publications are hereby incorporated herein by reference as if set forth in full herein.

The electrochemical deposition process may be carried out in a number of different ways as set forth in the above patent and publications. In one form, this process involves the execution of three separate operations during the formation of each layer of the structure that is to be formed:
1. Selectively depositing at least one material by electrodeposition upon one or more desired regions of a substrate.
2. Then, blanket depositing at least one additional material by electrodeposition so that the additional deposit covers both the regions that were previously selectively deposited onto, and the regions of the substrate that did not receive any previously applied selective depositions.

3. Finally, planarizing the materials deposited during the first and second operations to produce a smoothed surface of a first layer of desired thickness having at least one region containing the at least one material and at least one region containing at least the one additional material.

After formation of the first layer, one or more additional layers may be formed adjacent to the immediately preceding layer and adhered to the smoothed surface of that preceding layer. These additional layers are formed by repeating the first through third operations one or more times wherein the formation of each subsequent layer treats the previously formed layers and the initial substrate as a new and thickening substrate.

Once the formation of all layers has been completed, at least a portion of at least one of the materials deposited is generally removed by an etching process to expose or release the three-dimensional structure that was intended to be formed.

The preferred method of performing the selective electrodeposition involved in the first operation is by conformable contact mask plating. In this type of plating, one or more conformable contact (CC) masks are first formed. The CC masks include a support structure onto which a patterned conformable dielectric material is adhered or formed. The conformable material for each mask is shaped in accordance with a particular cross-section of material to be plated. At least one CC mask is needed for each unique cross-sectional pattern that is to be plated.

The support for a CC mask is typically a plate-like structure formed of a metal that is to be selectively electroplated and from which material to be plated will be dissolved. In this typical approach, the support will act as an anode in an electroplating process. In an alternative approach, the support may instead be a porous or otherwise perforated material through which deposition material will pass during an electroplating operation on its way from a distal anode to a deposition surface. In either approach, it is possible for CC masks to share a common support, i.e. the patterns of conformable dielectric material for plating multiple layers of material may be located in different areas of a single support structure. When a single support structure contains multiple plating patterns, the entire structure is referred to as the CC mask while the individual plating masks may be referred to as “submasks”. In the present application such a distinction will be made only when relevant to a specific point being made.

In preparation for performing the selective deposition of the first operation, the conformable portion of the CC mask is placed in registration with and pressed against a selected portion of the substrate (or onto a previously formed layer or onto a previously deposited portion of a layer) on which deposition is to occur. The pressing together of the CC mask and substrate occur in such a way that all openings, in the conformable portions of the CC mask contain plating solution. The conformable material of the CC mask that contacts the substrate acts as a barrier to electrodeposition while the openings in the CC mask that are filled with electroplating solution act as pathways for transferring material from an anode (e.g. the CC mask support) to the non-contacted portions of the substrate (which act as a cathode during the plating operation) when an appropriate potential and/or current are supplied.

An example of a CC mask and CC mask plating are shown in FIGS. 1A-1C. FIG. 1A shows a side view of a CC mask 8 consisting of a conformable or deformable (e.g. elastomeric) insulator 10 patterned on an anode 12. The anode has two functions. FIG. 1A also depicts a substrate 6 separated from mask 8. One is as a supporting material for the patterned insulator 10 to maintain its integrity and alignment since the pattern may be topologically complex (e.g., involving isolated “islands” of insulator material). The other function is as an anode for the electroplating operation. CC mask plating selectively deposits material 22 onto a substrate 6 by simply pressing the insulator against the substrate then electrodepositing material through apertures 26a and 26b in the insulator as shown in FIG. 1B. After deposition, the CC mask is separated, preferably non-destructively, from the substrate 6 as shown in FIG. 1C. The CC mask plating process is distinct from a “through-mask” plating process in that in a through-mask plating process the separation of the masking material from the substrate would occur destructively. As with through-mask plating, CC mask plating deposits material selectively and simultaneously over the entire layer. The plated region may consist of one or more isolated plating regions where these isolated plating regions may belong to a single structure that is being formed or may belong to multiple structures that are being formed simultaneously. In CC mask plating as individual masks are not intentionally destroyed in the removal process, they may be usable in multiple plating operations.

Another example of a CC mask and CC mask plating is shown in FIGS. 1D-1F. FIG. 1D shows an anode 12′ separated from a mask 8′ that comprises a patterned conformable material 10′ and a support structure 20. FIG. 1D also depicts substrate 6 separated from the mask 8′. FIG. 1E illustrates the mask 8′ being brought into contact with the substrate 6. FIG. 1F illustrates the deposit 22′ that results from conducting a current from the anode 12′ to the substrate 6. FIG. 1G illustrates the deposit 22′ on substrate 6 after separation from mask 8′. In this example, an appropriate electrolyte is located between the substrate 6 and the anode 12′ and a current of ions coming from one or both of the solution and the anode are conducted through the opening in the mask to the substrate where material is deposited. This type of mask may be referred to as an anodeless INSTANT MASK™ (AIM) or as an anodeless conformable contact (ACC) mask.

Unlike through-mask plating, CC mask plating allows CC masks to be formed completely separate from the fabrication of the substrate on which plating is to occur (e.g. separate from a three-dimensional (3D) structure that is being formed). CC masks may be formed in a variety of ways, for example, a photolithographic process may be used. All masks can be generated simultaneously, prior to structure fabrication rather than during it. This separation makes possible a simple, low-cost, automated, self-contained, and internally-clean “desktop factory” that can be installed almost anywhere to fabricate 3D structures, leaving any required clean room processes, such as photolithography to be performed by service bureaus or the like.

An example of the electrochemical fabrication process discussed above is illustrated in FIGS. 2A-2F. These figures show that the process involves deposition of a first material 2 which is a sacrificial material and a second material 4 which is a structural material. The CC mask 8, in this example, includes a patterned conformable material (e.g. an elastomeric dielectric material) 10 and a support 12 which is made from deposition material 2. The conformal portion of the CC mask is pressed against substrate 6 with a plating solution 14 located within the openings 16 in the conformable material 10. An electric current, from power supply 18, is then passed through the plating solution 14 via (a) support 12 which doubles as an anode and (b) substrate 6 which doubles as a cathode. FIG. 2A, illustrates that the passing of current causes material 2 within the plating solution and material 2 from the anode 12 to be selectively transferred to and plated on the cathode 6. After electroplating the first deposition material 2 onto the substrate 6 using CC mask 8, the CC mask 8 is removed as shown in FIG. 2B. FIG. 2C depicts the second deposition material 4 as having been blanket-deposited (i.e. non-selectively deposited) over the previously deposited first deposition material 2 as well as over the other portions of the substrate 6. The blanket deposition occurs by electroplating from an anode (not shown), composed of the second material, through an appropriate plating solution (not shown), and to the cathode/substrate 6. The entire two-material layer is then planarized to achieve precise thickness and flatness as shown in FIG. 2D. After repetition of this process for all layers, the multi-layer structure 20 formed of the second material 4 (i.e. structural material) is embedded in first material 2 (i.e. sacrificial material) as shown in FIG. 2E. The embedded structure is etched to yield the desired device, i.e. structure 20, as shown in FIG. 2F.

Various components of an exemplary manual electrochemical fabrication system 32 are shown in FIGS. 3A-3C. The system 32 consists of several subsystems 34, 36, 38, and 40. The substrate holding subsystem 34 is depicted in the upper portions of each of FIGS. 3A to 3C and includes several components: (1) a carrier 48, (2) a metal substrate 6 onto which the layers are deposited, and (3) a linear slide 42 capable of moving the substrate 6 up and down relative to the carrier 48 in response to drive force from actuator 44. Subsystem 34 also includes an indicator 46 for measuring differences in vertical position of the substrate which may be used in setting or determining layer thicknesses and/or deposition thicknesses. The subsystem 34 further includes feet 68 for carrier 48 which can be precisely mounted on subsystem 36.

The CC mask subsystem 36 shown in the lower portion of FIG. 3A includes several components: (1) a CC mask 8 that is actually made up of a number of CC masks (i.e. submasks) that share a common support/anode 12, (2) precision X-stage 54, (3) precision Y-stage 56, (4) frame 72 on which the feet 68 of subsystem 34 can mount, and (5) a tank 58 for containing the electrolyte 16. Subsystems 34 and 36 also include appropriate electrical connections (not shown) for connecting to an appropriate power source for driving the CC masking process.

The blanket deposition subsystem 38 is shown in the lower portion of FIG. 3B and includes several components: (1) an anode 62, (2) an electrolyte tank 64 for holding plating solution 66, and (3) frame 74 on which the feet 68 of subsystem 34 may sit. Subsystem 38 also includes appropriate electrical connections (not shown) for connecting the anode to an appropriate power supply for driving the blanket deposition process.

The planarization subsystem 40 is shown in the lower portion of FIG. 3C and includes a lapping plate 52 and associated motion and control systems (not shown) for planarizing the depositions.

Another method for forming microstructures from electroplated metals (i.e. using electrochemical fabrication techniques) is taught in U.S. Pat. No. 5,190,637 to Henry Guckel, entitled “Formation of Microstructures by Multiple Level Deep X-ray Lithography with Sacrificial Metal layers”. This patent teaches the formation of metal structure utilizing mask exposures. A first layer of a primary metal is electroplated onto an exposed plating base to fill a void in a photoresist, the photoresist is then removed and a secondary metal is electroplated over the first layer and over the plating base. The exposed surface of the secondary metal is then machined down to a height which exposes the first metal to produce a flat uniform surface extending across the both the primary and secondary metals. Formation of a second layer may then begin by applying a photoresist layer over the first layer and then repeating the process used to produce the first layer. The process is then repeated until the entire structure is formed and the secondary metal is removed by etching. The photoresist is formed over the plating base or previous layer by casting and the voids in the photoresist are formed by exposure of the photoresist through a patterned mask via X-rays or UV radiation.

Electrochemical Fabrication provides the ability to form prototypes and commercial quantities of miniature objects, parts, structures, devices, and the like at reasonable costs and in reasonable times. In fact, Electrochemical Fabrication is an enabler for the formation of many structures that were hitherto impossible to produce. Electrochemical Fabrication opens the spectrum for new designs and products in many industrial fields. Even though Electrochemical Fabrication offers this new capability and it is understood that Electrochemical Fabrication techniques can be combined with designs and structures known within various fields to produce new structures, certain uses for Electrochemical Fabrication provide designs, structures, capabilities and/or features not known or obvious in view of the state of the art.

A need exists in various fields for miniature devices having improved characteristics, reduced fabrication times, reduced fabrication costs, simplified fabrication processes, and/or more independence between geometric configuration and the selected fabrication process. A need also exists in the field of miniature (i.e. mesoscale and microscale) device fabrication for improved fabrication methods and apparatus.

A need also exists in the electrochemical fabrication field for enhanced techniques that supplement those already known in the field to allow even greater versatility in device design, improved selection of materials, improved material properties, more cost effective and less risky production of such devices, and the like.

### SUMMARY OF THE INVENTION

It is an object of some aspects of the invention to provide an electrochemical fabrication technique capable of fabricating improved probe array structures.

It is an object of some aspects of the invention to provide an improved electrochemical fabrication technique capable of fabricating probe array structures.

Other objects and advantages of various aspects of the invention will be apparent to those of skill in the art upon review of the teachings herein. The various aspects of the invention, set forth explicitly herein or otherwise ascertained from the teachings herein, may address one or more of the above objects alone or in combination, or alternatively may address some other object of the invention ascertained from the teachings herein. It is not necessarily intended that all objects be addressed by any single aspect of the invention even though that may be the case with regard to some aspects.

A first aspect of the invention provides a method for fabricating a microprobe array, including: fabricating at least a portion of each of a plurality of probes on a temporary substrate; transferring the probes from the temporary substrate to a permanent substrate.

A second aspect of the invention provides a method for fabricating a microprobe, including: fabricating at least a portion of the microprobe on a temporary substrate; transferring the microprobe from the temporary substrate to a permanent substrate.

A third aspect of the invention provides a method for fabricating a compliant electrical contact element array, including: fabricating at least a portion of the compliant electrical contact elements on a temporary substrate; transferring the compliant electrical contact elements from the temporary substrate to a permanent substrate.

A fourth aspect of the invention provides a method for fabricating a compliant electrical contact element adhered to a permanent substrate, including: fabricating at least a portion of the compliant electrical contact element on a temporary substrate; transferring the compliant electrical contact element from the temporary substrate to a permanent substrate.

Aspects of the invention will be understood by those of skill in the art upon reviewing the teachings herein. Other aspects of the invention may involve combinations of the above noted aspects of the invention. Other aspects of the invention may involve apparatus that can be used in implementing one or more of the above method aspects of the invention. These other aspects of the invention may provide various combinations of the aspects presented above as well as provide other configurations, structures, functional relationships, and processes that have not been specifically set forth above.

### BRIEF DESCRIPTION OF THE DRAWINGS

FIGS. 1A-1C schematically depict side views of various stages of a CC mask plating process, while FIGS. 1D-1G schematically depict a side views of various stages of a CC mask plating process using a different type of CC mask.

FIGS. 2A-2F schematically depict side views of various stages of an electrochemical fabrication process as applied to the formation of a particular structure where a sacrificial material is selectively deposited while a structural material is blanket deposited.

FIGS. 3A-3C schematically depict side views of various example subassemblies that may be used in manually implementing the electrochemical fabrication method depicted in FIGS. 2A-2F.

FIGS. 4A-4I schematically depict the formation of a first layer of a structure using adhered mask plating where the blanket deposition of a second material overlays both the openings between deposition locations of a first material and the first material itself.

FIG. 5 provides a block diagram of a process of a first generalized embodiment of an aspect of the invention calling for the formation of at least a portion of plurality of probes on a temporary substrate then transferring them to a permanent substrate.

FIG. 6 provides a block diagram of a process of a first variation of the first generalized embodiment where the probes are transferred to the permanent substrate one at a time.

FIG. 7 provides a block diagram of a process of a second variation of the first generalized embodiment where the probes are transferred to the permanent substrate simultaneously as an array.

FIG. 8 provides a block diagram of a process of a third variation of the first generalized embodiment where the probes are transferred to the permanent substrate as a series of separately placed arrays.

FIG. 9 provides a block diagram of a process of a fourth variation of the first generalized embodiment where the probes are formed tips first and mounting regions last and thereafter transfer to the permanent substrate occurs, and then the temporary substrate is removed.

FIG. 10 provides a block diagram of a process of a fifth variation of the first generalized embodiment where the probes are formed tips first and mounting regions last and thereafter the temporary substrate is removed, and then transfer to the permanent substrate occurs.

FIG. 11 provides a block diagram of a process of a sixth variation of the first generalized embodiment where the probes are formed mounting regions first and tips last, thereafter the temporary substrate is removed, and then the permanent substrate attached.

FIG. 12 provides a block diagram of a process of a seventh variation of the first generalized embodiment where the probes are formed mounting regions first and tips last, thereafter a second temporary substrate is attached, and then the first temporary substrate is removed and the permanent substrate attached in its place.

FIG. 13 provides a block diagram of a process of a eighth variation of the first generalized embodiment where the probes are formed only in part prior to transfer to the permanent substrate and thereafter fabrication of the probes is completed.

FIG. 14 provides a block diagram of a process of a seventh variation of the first generalized embodiment where the probes are released at least in part from a sacrificial material prior to transfer to the permanent substrate.

FIG. 15 provides a block diagram of a process of an ninth variation of the first generalized embodiment where the probes are not released from at least one sacrificial material prior to transfer to the permanent substrate and thereafter the probes are released from the at least one sacrificial material.

FIG. 16 provides a block diagram of a process of a tenth variation of the first generalized embodiment where formation of the probes includes the selective placement of a conductive adhesion material on the mounting regions of the probes prior to contacting the probes to the permanent substrate.

FIG. 17 provides a block diagram of a process of an eleventh variation of the first generalized embodiment wherein a conductive adhesion material is selectively placed at locations on the permanent substrate where attachment to probes is to be made and thereafter the probes and the permanent substrate are attached.

FIG. 18 provides a block diagram of a process of an twelfth variation of the first generalized where formation of the probes includes the selective placement of a first conductive adhesion material on the mounting regions of the probes prior to contacting the probes to the permanent substrate and wherein a fourteenth conductive adhesion material is selectively placed at locations on the permanent substrate where attachment to probes is to be made and thereafter the probes and the permanent substrate are attached using the first and second adhesion materials.

FIG. 19 provides a block diagram of a process of a thirteenth variation of the first generalized embodiment where at least a portion of the sacrificial material is not removed prior to transfer and wherein a protective material is located between the adhesion material and any sacrificial material during the bonding of the permanent substrate and the probes.

FIG. 20 provides a block diagram of a process of first extension of the thirteenth variation of the first generalized embodiment which includes the removal of the sacrificial material and the protective material after bonding.

FIG. 21 provides a block diagram of a process of second extension of the thirteenth variation of the first generalized embodiment which includes the removal of the sacrificial material but the retention of the protective material after bonding.

FIG. 22 provides a block diagram of a process of a fourteenth variation of the first generalized embodiment where the probes are heat treated prior to bonding to improve adhesion between layers of a structural material from which the probes have been formed.

FIG. 23 provides a block diagram of a process of a fifteenth variation of the first generalized embodiment where the probes are heat treated after bonding to improve adhesion between layers of a structural material from which the probes have been formed.

FIGS. 24A-24C depict schematic perspective views of three stages of an example of a process where multiple probe arrays are formed upside down, diced, and then transferred to a permanent substrate to form larger array groups as was exemplified in the block diagram of FIG. 8.

FIGS. 25A-25J depict schematic side views of various states of an example of a process for forming a multilayer two element probe array on a temporary substrate and then transferring and bonding the formed structures to a permanent substrate where the substrate is composed of the sacrificial material and where the process includes elements exemplified in the block diagrams of FIGS. 9 and 15.

FIGS. 26A-26E depict schematic side views of various states of an example of a process for forming multiple, multilayer, multi-element probe arrays on a temporary substrate and then transferring and bonding the formed structures to a permanent substrate where the tips of the probe elements are molded in a patterned substrate, and diffusion bonding occurs prior to release but after transfer and bonding and where the process includes elements exemplified in the block diagrams of FIGS. 9, 15, and 23.

FIGS. 27A-27C depict schematic side views of various states of a process that forms enhanced probe tips on the probes of FIGS. 26A-26E.

FIGS. 28A-28I depict schematic side views of various states of an example of a process for forming multilayer, multi-element probe arrays on a temporary substrate and then transferring and bonding the formed structures to a permanent substrate where the tips of the probe elements are molded in a patterned substrate of a tip material which may be different from a structural material, where prior to transfer a individual probe arrays are analyzed for high yield probability and thereafter selected for use or non-use, and where the process includes elements exemplified in the block diagrams of FIGS. 9, 15, and 23.

FIGS. 29A-29L depict schematic side views of various states of an example of a process for forming multilayer, multi-element probe arrays on a temporary substrate and then transferring and bonding the formed structures to a permanent substrate where the probe tips are shaped via a mold formed from sacrificial material, where the probe elements are separated from the temporary substrate by a meltable material, and where the process includes elements exemplified in the block diagrams of FIGS. 9, 15, and 22.

FIGS. 30A-30H depict schematic side views of various states of an example of a process for forming multilayer, multi-element probe arrays on a temporary substrate which is similar to that shown in FIGS. 29A-29L with the exception that the first metal is replaced by a dielectric material.

FIGS. 31A-31W depict schematic side views of various states of another example of a process for forming multilayer, multi-element probe array on a temporary substrate.

FIGS. 32A-32Z depict schematic side views of various states of an example process which is similar to that of FIGS. 31A-31W but which additionally involves coating the probe

### DETAILED DESCRIPTION OF PREFERRED EMBODIMENTS OF THE INVENTION

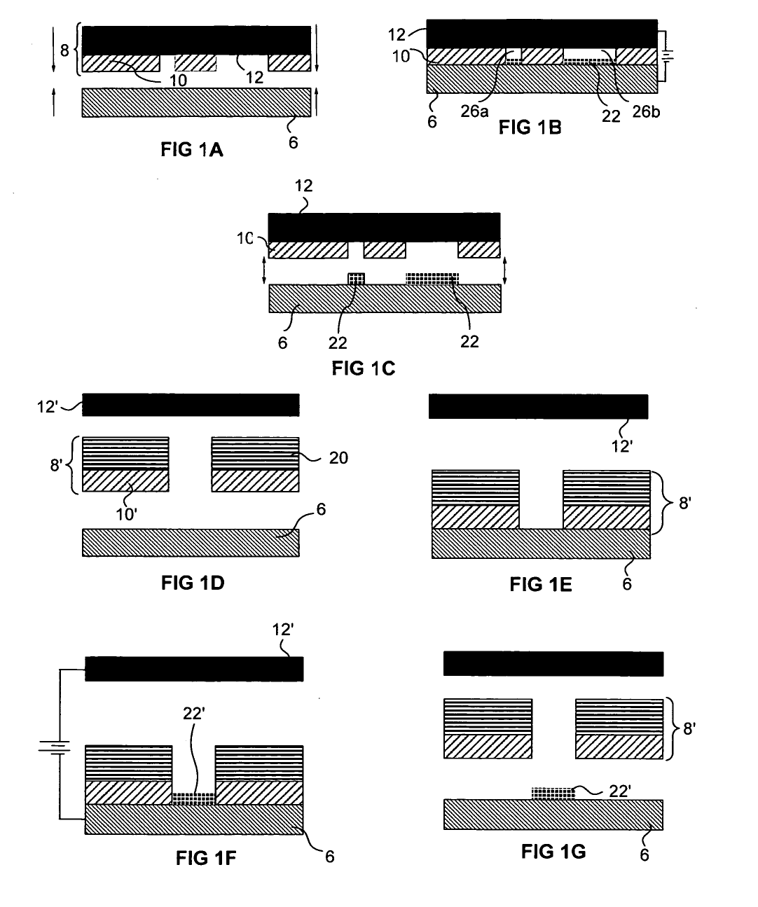

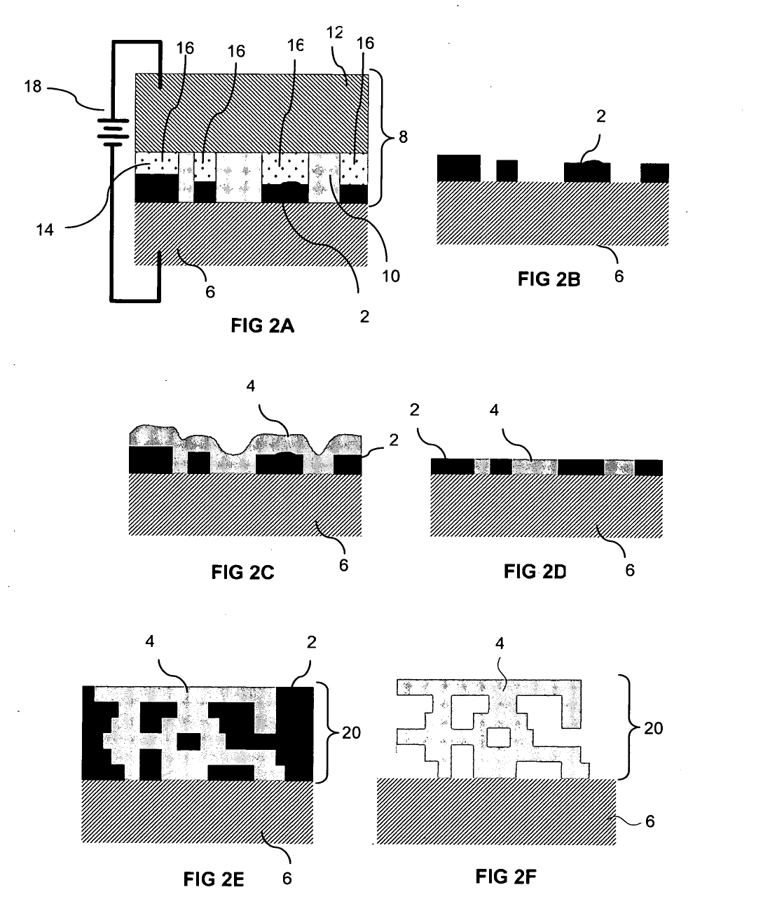

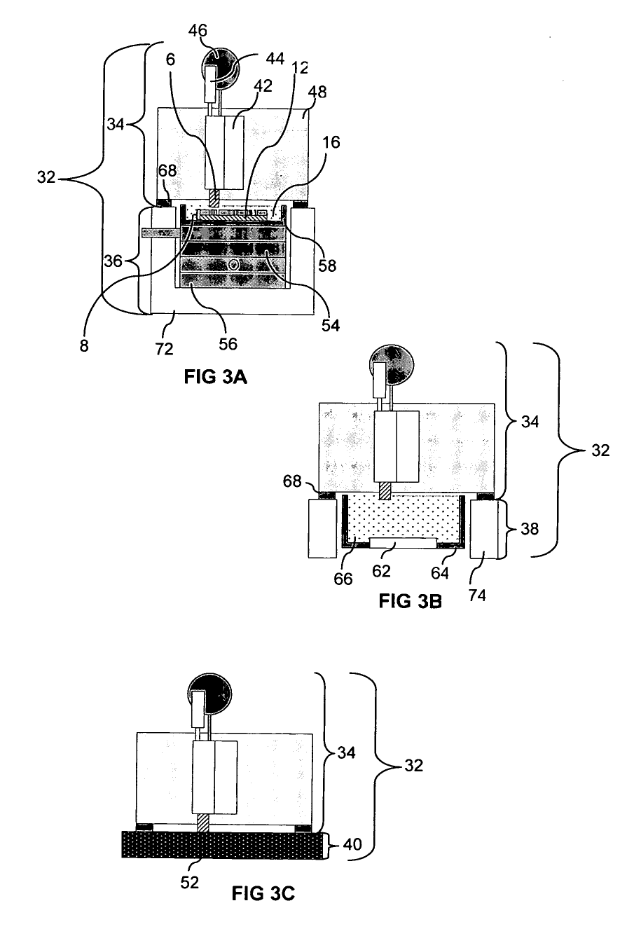

FIGS. 1A-1G, 2A-2F, and 3A-3C illustrate various features of one form of electrochemical fabrication that are known. Other electrochemical fabrication techniques are set forth in the '630 patent referenced above, in the various previously incorporated publications, in various other patents and patent applications incorporated herein by reference, still others may be derived from combinations of various approaches described in these publications, patents, and applications, or are otherwise known or ascertainable by those of skill in the art from the teachings set forth herein. All of these techniques may be combined with those of the various embodiments of various aspects of the invention to yield enhanced embodiments. Still other embodiments may be derived from combinations of the various embodiments explicitly set forth herein.

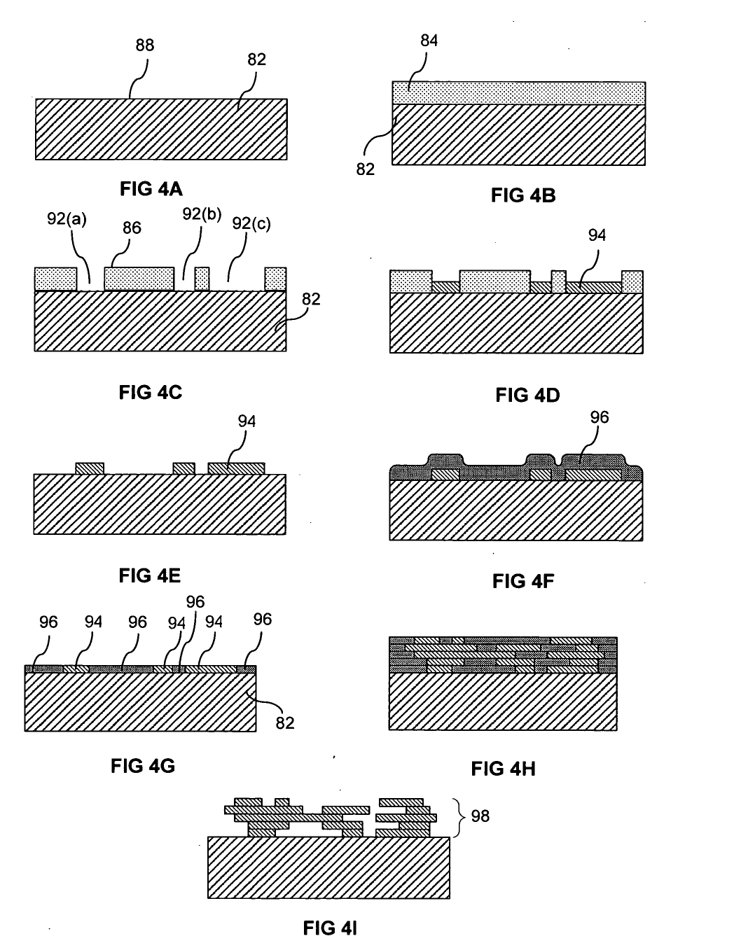

FIGS. 4A-4I illustrate various stages in the formation of a single layer of a multi-layer fabrication process where a second metal is deposited on a first metal as well as in openings in the first metal where its deposition forms part of the layer. In FIG. 4A, a side view of a substrate 82 is shown, onto which patternable photoresist 84 is cast as shown in FIG. 4B. In FIG. 4C, a pattern of resist is shown that results from the curing, exposing, and developing of the resist. The patterning of the photoresist 84 results in openings or apertures 92(a)-92(c) extending from a surface 86 of the photoresist through the thickness of the photoresist to surface 88 of the substrate 82. In FIG. 4D, a metal 94 (e.g. nickel) is shown as having been electroplated into the openings 92(a)-92(c). In FIG. 4E, the photoresist has been removed (i.e. chemically stripped) from the substrate to expose regions of the substrate 82 which are not covered with the first metal 94. In FIG. 4F, a second metal 96 (e.g., silver) is shown as having been blanket electroplated over the entire exposed portions of the substrate 82 (which is conductive) and over the first metal 94 (which is also conductive). FIG. 4G depicts the completed first layer of the structure which has resulted from the planarization of the first and second metals down to a height that exposes the first metal and sets a thickness for the first layer. In FIG. 4H the result of repeating the process steps shown in FIGS. 4B-4G several times to form a multi-layer structure are shown where each layer consists of two materials. For most applications, one of these materials is removed as shown in FIG. 4I to yield a desired 3-D structure 98 (e.g. component or device).

The various embodiments, alternatives, and techniques disclosed herein may form multi-layer structures using a single patterning technique on all layers or using different patterning techniques on different layers. For example, different types of patterning masks and masking techniques may be used on some layers while direct selective depositions may be used during the formation of other layers. For example, conformable contact masks and/or non-conformable contact masks and masking operations may be used on some layers while other layers may be formed using other techniques. Proximity masks and masking operations (i.e. operations that use masks that at least partially selectively shield a substrate by their proximity to the substrate even if contact is not made) may be used, and adhered masks and masking operations (masks and operations that use masks that are adhered to a substrate onto which selective deposition or etching is to occur as opposed to only being contacted to it) may be used.

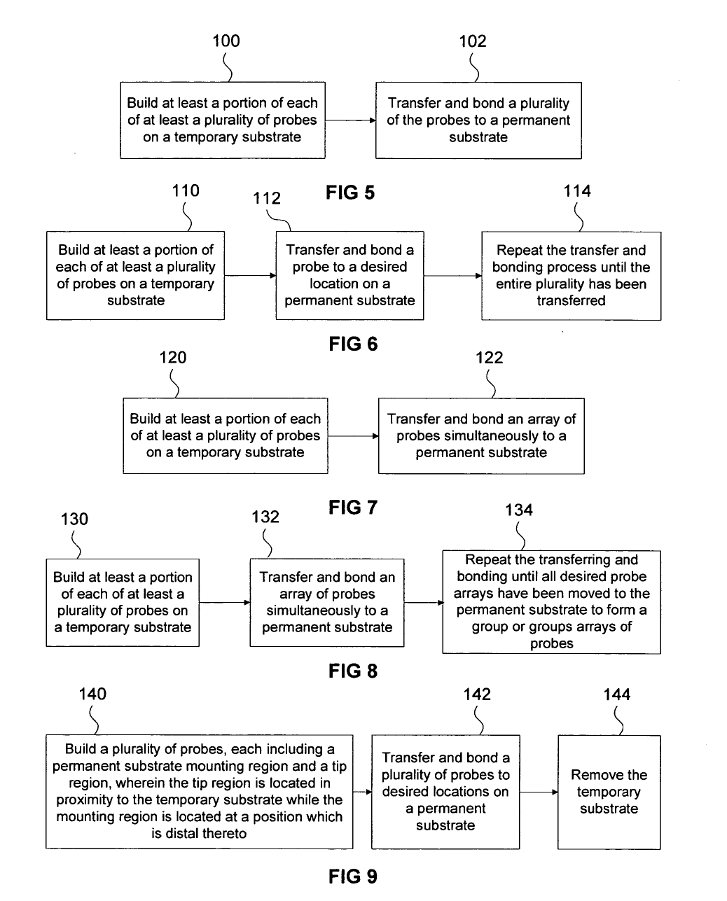

FIG. 5 provides a block diagram of a process of a first generalized embodiment of an aspect of the invention calling for the formation of at least a portion of plurality of probes on a temporary substrate then transferring them to a permanent substrate.

Block 100 calls for the building of at least a portion of each of at least a plurality of probes on a temporary substrate. The building operations of block 100 may be implemented in a variety of different ways. For example, the building operations may include electrochemical fabrication operations such as those described herein earlier as well as those described in the various patents and patent applications incorporated herein by reference. The building operations may include the use of more then one structural material on some layers and or the use of more then one sacrificial material on some layers.

Building techniques may include the use of more then one planarization operation per layer and in some cases the use of no planarization operations on some layers. Deposition operations may be of the selective and/or blanket type and etching operations may be performed on the selective or blanket type. Depositions may include electroplating operations, electrophoretic deposition operations, electroless plating operations, various physical and chemical vapor deposition operations, thermal spray metal deposition operations, and the like. Materials deposited may be all of the conductive type or some may be dielectrics. Further deposition techniques may include flowing over, spreading, spraying, ink jet dispensing, and the like. Sacrificial materials may be separable from structural materials by selective chemical etching operations, planarization operations, melting operations, and the like.

Block 102 calls for the transfer and bonding of a plurality of the probes to a permanent substrate. The permanent substrate may be, for example, a space transformer or other dielectric material with selected conductive paths extending through it and connecting to the plurality of probes in a desired manner. Various alternatives for implementing the transfer and bonding process are possible, some examples of which will be discussed hereinafter.

The probes formed may take on a variety of configurations, some of which are described in U.S. Patent Application No. 60/533,933, which was filed Dec. 31, 2003 by Arat et al, and which is entitled “Electrochemically Fabricated Microprobes”.

The probes may include tips which are formed in any of a variety of different ways and which may take on a variety of different shapes. Examples of such tip configurations and formation methods are included in U.S. Patent Application No. 60/533,975, which was filed Dec. 31, 2003 by Kim et al. and which is entitled “Microprobe Tips and Methods for Making”.

In some embodiments, it may be desirable to form probes from multiple materials. Examples of techniques for forming such multiple material probes are provided in U.S. Patent Application No. 60/533,897 filed Dec. 31, 2003 by Cohen et al. and which is entitled “Electrochemical Fabrication Process for Forming Multilayer Multimaterial Microprobe structures”.

In some embodiments the formation of the probes may include various post layer formation operations which may occur before or after transfer and bonding to the permanent substrate. Some such operations may include diffusion bonding techniques which tend to enhance interlayer adhesion. Some embodiments may employ diffusion bonding or the like to enhance adhesion between successive layers of material. Various teachings concerning the use of diffusion bonding in electrochemical fabrication process is set forth in U.S. Patent Application No. 60/534,204 which was filed Dec. 31, 2003 by Cohen et al. which is entitled “Method for Fabricating Three-Dimensional Structures Including Surface Treatment of a First Material in Preparation for Deposition of a Second Material” and which is hereby incorporated herein by reference as if set forth in full.

As noted above the formation of the probes may involve a use of structural or sacrificial dielectric materials which may be incorporated into embodiments of the present invention in a variety of different ways. Additional teachings concerning the formation of structures on dielectric substrates and/or the formation of structures that incorporate dielectric materials into the formation process and possibility into the final structures as formed are set forth in a number of patent applications filed Dec. 31, 2003. The first of these filings is U.S. Patent Application No. 60/534,184 which is entitled “Electrochemical Fabrication Methods Incorporating Dielectric Materials and/or Using Dielectric Substrates”. The second of these filings is U.S. Patent Application No. 60/533,932, which is entitled “Electrochemical Fabrication Methods Using Dielectric Substrates”. The third of these filings is U.S. Patent Application No. 60/534,157, which is entitled “Electrochemical Fabrication Methods Incorporating Dielectric Materials”. The fourth of these filings is U.S. Patent Application No. 60/533,891, which is entitled “Methods for Electrochemically Fabricating Structures Incorporating Dielectric Sheets and/or Seed layers That Are Partially Removed Via Planarization”. A fifth such filing is U.S. Patent Application No. 60/533,895, which is entitled “Electrochemical Fabrication Method for Producing Multi-layer Three-Dimensional Structures on a Porous Dielectric”. These patent filings are each hereby incorporated herein by reference as if set forth in full herein.

Further teachings about planarizing layers and setting layers thicknesses and the like are set forth in the following US patent applications which were filed Dec. 31, 2003: (1) U.S. Patent Application No. 60/534,159 by Cohen et al. and which is entitled “Electrochemical Fabrication Methods for Producing Multilayer Structures Including the use of Diamond Machining in the Planarization of Deposits of Material” and (2) U.S. Patent Application No. 60/534,183 by Cohen et al. and which is entitled “Method and Apparatus for Maintaining Parallelism of Layers and/or Achieving Desired Thicknesses of Layers During the Electrochemical Fabrication of Structures”. These patent filings are each hereby incorporated herein by reference as if set forth in full herein.

Each of the patent applications set forth in the above paragraphs are incorporated herein by reference as if set forth in full.

FIG. 6 provides a block diagram of a process of a first variation of the first generalized embodiment where the probes are transferred to the permanent substrate one at a time.

Block 110 of FIG. 6 is similar to block 100 of FIG. 5 as it calls for the building of at least a portion of a plurality of probes on a temporary substrate.

Block 112 of FIG. 6 calls for the transfer and bonding of a single probe to a desired location on a permanent substrate while block 114 calls for the repeating of the transfer and bonding operation a plurality of times until a desired plurality of probes have been transferred.

FIG. 7 provides a block diagram of a process of a second variation of the first generalized embodiment where the probes are transferred to the permanent substrate simultaneously as an array.

Block 120 of FIG. 7 is similar to blocks 110 and 100 of FIGS. 6 and 5 respectively in that it calls for the building of at least a portion of at least a plurality of probes on a temporary substrate.

Block 122 calls for the transfer and bonding of an array of probes simultaneously to a permanent substrate.

FIG. 8 provides a block diagram of a process of a third variation of the first generalized embodiment where the probes are transferred to the permanent substrate as a series of separately placed arrays.

Block 130 of FIG. 8 calls for the building of at least a portion of each of at least a plurality of probes on a temporary substrate. Block 132 of FIG. 8 calls for operations similar to those called for by block 122 of FIG. 7 which calls for the transfer and bonding of an array of probes simultaneously to a permanent substrate.

The process of FIG. 8 then continues on to block 134 which calls for repeating the transferring and bonding operations of block 132 one or more times until all desired probe arrays have been moved to the permanent substrate to form a group or groups of arrays of probes.

FIG. 9 provides a block diagram of a process of a fourth variation of the first generalized embodiment where the probes are formed tips first and mounting regions last and thereafter transfer to the permanent substrate occurs, and then the temporary substrate is removed.

Block 140 of FIG. 9 calls for the formation of a plurality of probes where each probe includes a permanent substrate mounting region and a tip region. The tip region is located in proximity to a temporary substrate on which the probes are formed and the mounting region is located at a position which is distal to the temporary substrate. After formation of the probes the process moves forward to block 142 which calls for the transfer and bonding of a plurality of the probes to desired locations on a permanent substrate after which the process moves forward to block 144 which calls for the removal of the temporary substrate.

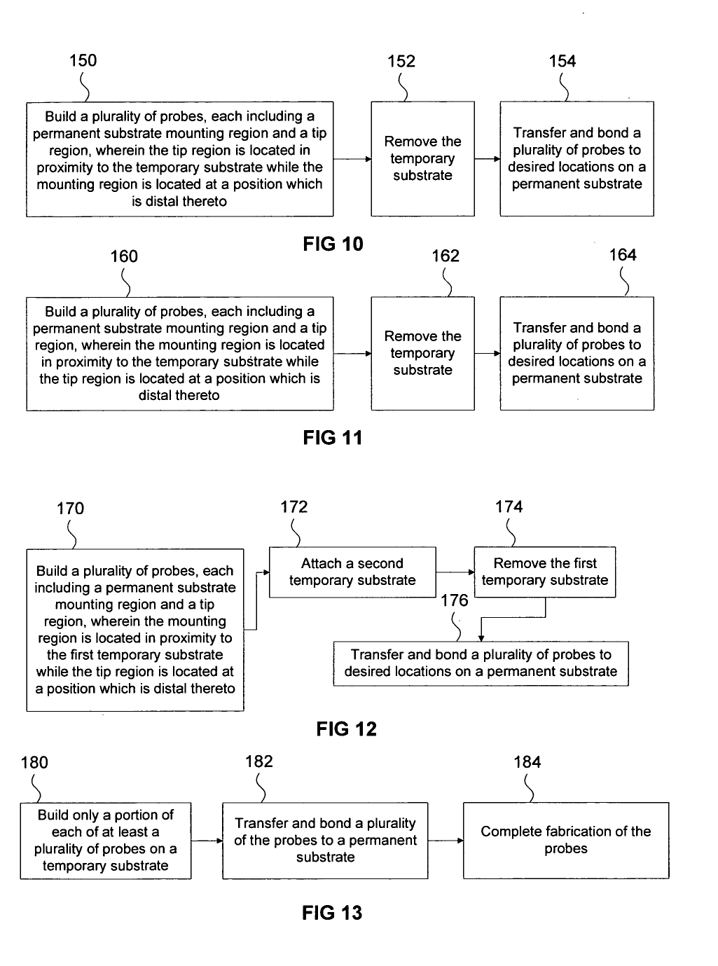

FIG. 10 provides a block diagram of a process of a fifth variation of the first generalized embodiment where the probes are formed tips first and mounting regions last and thereafter the temporary substrate is removed, and then transfer to the permanent substrate occurs.

The process of FIG. 10 is similar to that of FIG. 9 with the exception that the removal of the temporary substrate (block 152) occurs prior to the transfer and bonding of the plurality of probes to the permanent substrate (block 154).

FIG. 11 provides a block diagram of a process of a sixth variation of the first generalized embodiment where the probes are formed mounting regions first and tips last, thereafter the temporary substrate is removed, and then the permanent substrate attached.

The process of FIG. 11 is similar in many respects to that of FIG. 10 as bonding to the permanent substrate (block 164) follows removal of the probes from the temporary substrate (block 162) which occurs after formation of the probes (block 160). The difference between the process of FIG. 10 and that of FIG. 11 is in the process of building the probes (block 160) where the process of FIG. 11 involves forming the permanent substrate mounting region portion of the probes in proximity to the temporary substrate while the tips of the probes are formed at locations which are distal to the temporary substrate whereas the reverse is true in the process of FIG. 10.

Of course in further variations of the processes of FIGS. 10 and 11 it will be understood that other differences between the processes may also exist.

FIG. 12 provides a block diagram of a process of a seventh variation of the first generalized embodiment where the probes are formed mounting regions first and tips last, thereafter a second temporary substrate is attached, and then the first temporary substrate is removed and the permanent substrate attached in its place.

The process of FIG. 12 begins with block 170 which calls for the building of a plurality of probes where each probe includes a permanent substrate mounting region and a tip region and where the mounting region is located in proximity to a first temporary substrate on which the probes are formed while the tip region is located at a distal position.

After formation of the probes the process moves forward to block 172 which calls for the attachment of a second temporary substrate. In some implementations of this process the second temporary substrate may be attached to the probes in a plane that is substantially parallel to and opposing the mounting plain of the first temporary substrate.

In other implementations the secondary substrate may be mounted to one or more sides of the material or materials that make up the individual layers that formed the probes.

From block 172 the process moves forward to block 174 which calls for the removal of the first temporary substrate. And thereafter the process moves forward to block 176 which calls for the transfer and bonding of a plurality of probes to desired locations on a permanent substrate. The removal of the temporary substrate (block 174) must occur prior to the transfer and bonding to the permanent substrate as there is at least some overlap in positioning of the first temporary substrate and the locations where the permanent substrate is to be attached.

FIG. 13 provides a block diagram of a process of a eighth variation of the first generalized embodiment where the probes are formed only in part prior to transfer to the permanent substrate and thereafter fabrication of the probes is completed.

The process of FIG. 13 begins with block 180 which calls for the building of only a portion of each of at least a plurality of probes on a temporary substrate. After partial completion of the build the process moves forward to block 182 which calls for the transfer and bonding of a plurality of probes to a permanent substrate.

After completion of transfer the process moves forward to block 184 which calls for the completion of fabrication of the probes.

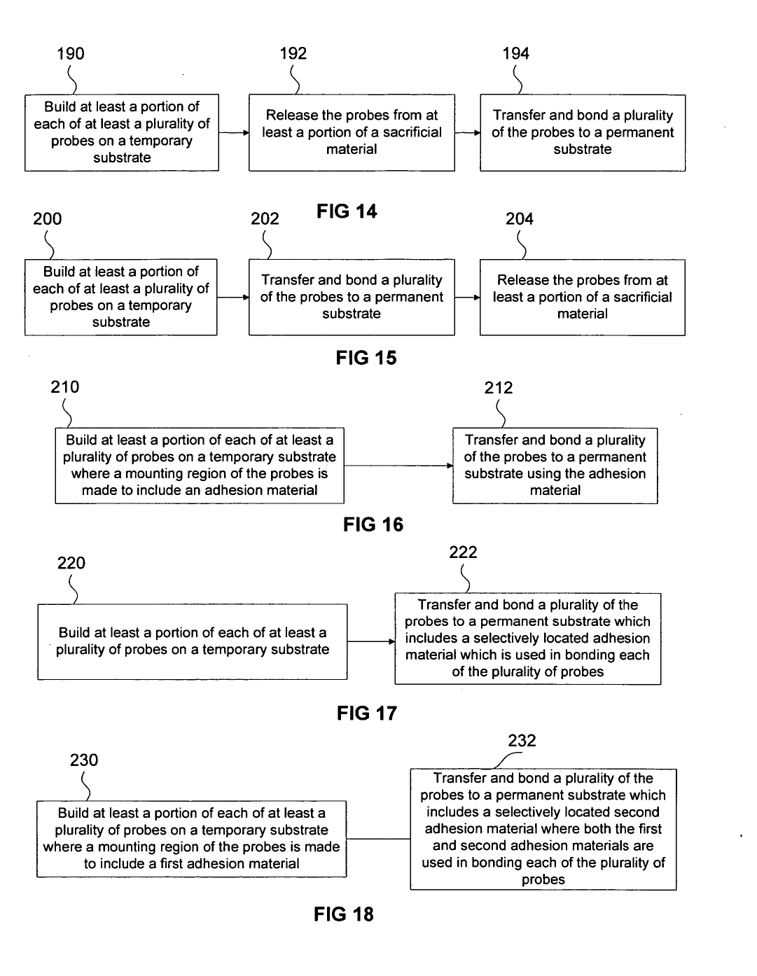

FIG. 14 provides a block diagram of a process of a seventh variation of the first generalized embodiment where the probes are released at least in part from a sacrificial material prior to transfer to the permanent substrate.

The process of FIG. 14 begins with block 190 which calls for the building of at least a portion of each of at least a plurality of probes on a temporary substrate.

After build up has proceeded to a desired level the process moves forward to block 192 which calls for the release of the probes from at least a portion of the sacrificial material that was used during the formation of the probes.

Next the process moves forward to block 194 which calls for transferring and bonding a plurality of the probes to a permanent substrate.

FIG. 15 provides a block diagram of a process of an ninth variation of the first generalized embodiment where the probes are not released from at least one sacrificial material prior to transfer to the permanent substrate and thereafter the probes are released from the at least one sacrificial material.

The process of FIG. 15 begins with the building of at least a portion of each of at least a plurality of probes on a temporary substrate as indicated in block 200. After the building has reached a desired level the probes are transferred and bonded to a permanent substrate as indicated by block 202.

After transfer and bonding the probes are released from at least a portion of a sacrificial material that was used during the build operation as indicated by block 204.

FIG. 16 provides a block diagram of a process of an tenth variation of the first generalized embodiment where formation of the probes includes the selective placement of a conductive adhesion material on the mounting regions of the probes prior to contacting the probes to the permanent substrate.

The process of FIG. 16 begins, as indicated in block 210, with the formation of at least a portion of each of at least a plurality of probes on a temporary substrate where the formation of the probes includes the formation of a mounting region which includes an adhesion material that will be used for bonding the probes to a permanent substrate. After formation of the probes including the placement of adhesion material the process moves forward to block 212 which calls for the transfer and bonding of a plurality of the probes to a permanent substrate using the adhesion material.

FIG. 17 provides a block diagram of a process of an eleventh variation of the first generalized embodiment wherein a conductive adhesion material is selectively placed at locations on the permanent substrate where attachment to probes is to be made and thereafter the probes and the permanent substrate are attached.

The process of FIG. 17 begins with block 220 which calls for the building of at least a portion of each of at least a plurality of probes on a temporary substrate after which the process moves forward to block 222 which calls for the transfer and bonding of a plurality of the probes to a permanent substrate where the permanent substrate includes selectively located adhesion material which is used in bonding the plurality of probes to the permanent substrate.

FIG. 18 provides a block diagram of a process of an twelfth variation of the first generalized embodiment where formation of the probes includes the selective placement of a first conductive adhesion material on the mounting regions of the probes prior to contacting the probes to the permanent substrate and wherein a second conductive adhesion material is selectively placed at locations on the permanent substrate where attachment to probes is to be made and thereafter the probes and the permanent substrate are attached using the first and second adhesion materials.

The process of FIG. 18 is in fact a merging of the processes set forth in FIGS. 16 and 17. The process of FIG. 18 begins with block 230 which calls for the building of at least a portion of each of at least a plurality of probes where a mounting region for the probes is also formed and which includes a first adhesion material.

Next the process moves forward to block 232 which calls for the transferring and bonding of a plurality of the probes to a permanent substrate where the permanent substrate was made to include selectively located regions of a second adhesion material wherein both the first and second adhesion materials are used in bonding the probes and the permanent substrate together.

In some implementations of this variation the first and second adhesion materials may be the same while in other implementations they may be different materials.

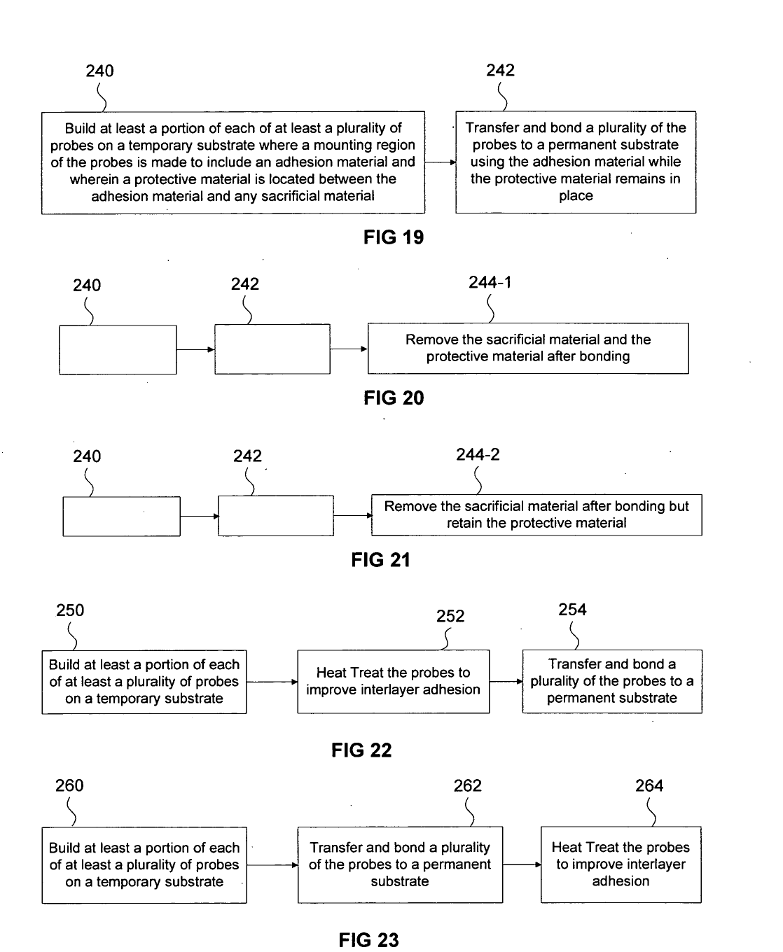

FIG. 19 provides a block diagram of a process of a thirteenth variation of the first generalized embodiment where at least a portion of the sacrificial material is not removed prior to transfer and wherein a protective material is located between the adhesion material and any sacrificial material during the bonding of the permanent substrate and the probes.

The process of FIG. 19 begins with block 240 which calls for the building of a plurality of probes on a temporary substrate where a mounting region of the probes is made to include an adhesion material and wherein a protective material is located between the adhesion material and any sacrificial material. After formation of the probes including the associated adhesion material and protective material the process moves forward to block 242 which calls for the transfer and bonding of a plurality of the probes to a permanent substrate and where the bonding is based at least in part on the use of the adhesion material and where the protective material remains in place at least during the bonding process.

FIG. 20 provides a block diagram of a process of first extension of the thirteenth variation of the first generalized embodiment which includes the removal of the sacrificial material and the protective material after bonding.

The process of FIG. 20 begins with the operations associated with blocks 240 and 242 as discussed above with regard to FIG. 19 and thereafter moves forward to block 244-1.

Block 244-1 calls for the removal of the sacrificial material and the removal of the protective material in some implementations of this variation. The protective material may be removed prior to the removal of the sacrificial material.

In still other implementations the sacrificial material may be removed prior to the removal of the protective material.

In still further implementations the sacrificial material and the protective material may be removed simultaneously.

FIG. 21 provides a block diagram of a process of second extension of the thirteenth variation of the first generalized embodiment which includes the removal of the sacrificial material but the retention of the protective material after bonding.

The process of FIG. 21 begins with the operations of block 240 and 242 as discussed above and thereafter proceeds to block 244-2.

Block 244-2 calls for the removal of the sacrificial material and the retention of the protective material. This retained protective material maybe useful in one or more ways, for example, it may be useful in stabilizing the positions of the probes relative to one another and it may also be useful in enhancing the adhesion between the probe array and the substrate.

FIG. 22 provides a block diagram of a process of a fourteenth variation of the first generalized embodiment where the probes are heat treated prior to bonding to improve adhesion between layers of a structural material from which the probes have been formed.

The process of FIG. 22 begins with block 250 which calls for the building of a plurality of probes on a temporary substrate. After the building of the probes the process moves forward to block 252 which calls for the heat treatment of the probes to improve adhesion between the layers of material from which the probe may have been formed.

After heat treatment the process moves forward to block 254 which calls for the transfer and bonding of the plurality of probes to a permanent substrate. In some implementations of the process of FIG. 22 the heat treatment may occur prior to removal of a sacrificial material and/or prior to separation of the probes from the temporary substrate.

In other implementations separation of the probes from the sacrificial material and/or the substrate may occur after heat treatment but before transfer and bonding while in still other implementations the separation from the sacrificial material and the temporary substrate may occur after transfer and bonding.

FIG. 23 provides a block diagram of a process of a fifteenth variation of the first generalized embodiment where the probes are heat treated after bonding to improve adhesion between layers of a structural material from which the probes have been formed.

The process of FIG. 23 begins with the formation of a plurality of probes on a temporary substrate as indicated by block 260 and thereafter moves forward to block 262 which calls for the transfer and bonding of the plurality of probes to a permanent substrate.

After transfer and bonding the process moves forward to block 264 which calls for the heat treatment of the probes to improve interlayer adhesion. In some implementations of the process of FIG. 23 separation of the probes from a sacrificial material and/or the temporary substrate may occur intermediate to the operations called for by blocks 260 and 262, intermediate to the operations called for by blocks 262 and 264 or after the operation called for by block 264.

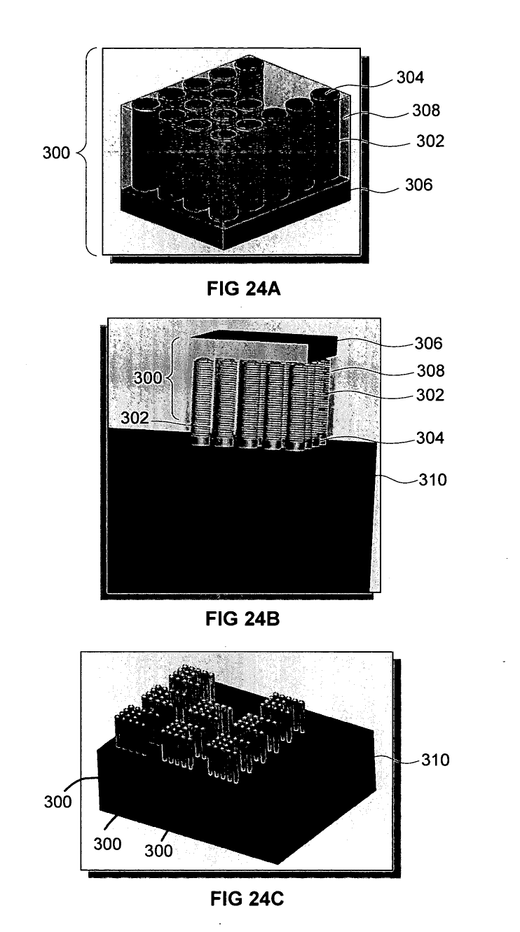

FIGS. 24A-24C depict schematic perspective views of three stages of an example of a process where multiple probe arrays are formed upside down, diced, and then transferred to a permanent substrate to form larger array groups as was exemplified in the block diagram of FIG. 8.

FIG. 24A depicts a state of the process after a plurality of probes 302 including adhesion materials 304 have been built from a plurality of adhered layers on a temporary substrate 306 and then diced into die 300.

FIG. 24B depicts a state of the process after an individual die 300 has been transferred to a permanent substrate 310 and contact made between probes 302 via adhesion material 304.

FIG. 24C depicts a state of the process after a number of operations have been performed. These operations include the release of probes 302 from sacrificial material 308, separation of the probes from temporary substrate 306, and the adhesion of a plurality of probe arrays 300 to permanent substrate 310.

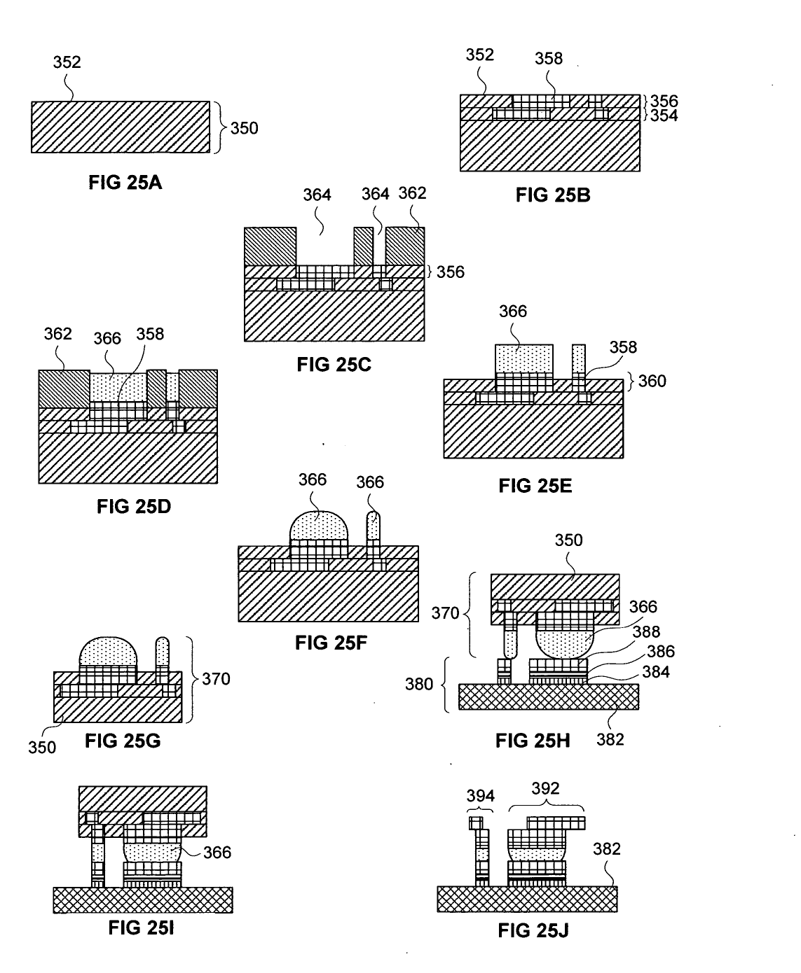

FIGS. 25A-25J depict schematic side views of various states of an example of a process for forming a multilayer two element probe array on a temporary substrate and then transferring and bonding the formed structures to a permanent substrate where the substrate is composed of the sacrificial material and where the process includes elements exemplified in the block diagrams of FIGS. 9 and 15.

FIG. 25A shows the state of the process after a substrate 352 is provided. The substrate 352 preferably is made of the sacrificial material that will be used during the formation of the structure. In some embodiments, for example, the substrate may be copper.

FIG. 25B shows the state of the process after formation of the layers of a multi-layer probe is completed. In FIG. 25B the probe is shown to be formed from a first layer 354 and a second layer 356. Each layer is made up from a structural material 358 and a sacrificial material 352. It will be understood by those of skill in the art that in practice probes may consist of more then the two layers exemplified in this figure.

FIG. 25C shows the state of the process after a masking material 362 has been contacted or adhered to layer 356 with openings 364 formed therein. The openings 364 correspond to locations where a last layer of structural material will be located along with an adhesion material.

FIG. 25D depicts a state of the process after openings 364 and mask 362 have received a deposition of structural material 358 and a deposition of adhesion material 366. In some variations of this process the structural material may be nickel and the adhesion material may be tin.

FIG. 25E shows the state of the process after masking material 362 has been removed to reveal the third layer 360 of structural material 358 over which adhesion material 366 has been deposited. In some variations of this process, for example, the masking material may be a liquid photoresist or a dry film photoresist which may be of the positive or negative type.

FIG. 25F shows the state of the process after adhesion material 366 has been reflowed to give it a rounded or balled shape.

FIG. 25G shows the state of the process after dicing has occurred to isolate individual dye and after slicing has occurred to trim down the thickness of the substrate 350. In variations of this process, prior to dicing and slicing the exposed portions of the probes and adhesion material may be covered with a protective material which may be readily separated from the formed structure, where after slicing and dicing the protective material would be removed (as shown in FIG. 25G).

FIG. 25H shows the state of the process after the overall structure and diced substrate 370 has been inverted and made to contact a permanent substrate laminate 380 which includes a permanent substrate 382, an adhesion layer material 384, a seed layer material 386, and a pad material 388.

In some variations of the embodiments pad material 388 may be the same as structural material 358. In other variations of the embodiment pad material 386 may be over-coated with an adhesion material prior to bringing laminate 380 and structure 370 into contact.

The selective locations of adhesion layer, seed layer, and pad material on permanent substrate 382 is selected to correspond to locations where contact with adhesion material on structure 370 is to occur. The alignment between structure 370 and pad locations 380 may initially be a rough alignment.

FIG. 25I shows the state of the process after adhesion material 366 is reflowed a second time which may result in further alignment of the probes with the pad locations and also will result in the adhesion of the probes to the permanent substrate.

FIG. 25J shows the state of the process after the temporary substrate is removed along with the removal of the sacrificial material making up a portion of the layers of the probes. FIG. 25J shows the completed state of the process where probe element 392 and probe element 394 are located on and adhered to permanent substrate 382. As can be seen in FIG. 25J not all probe structures in an array need to be of the same size or even of identical structuring or orientation.

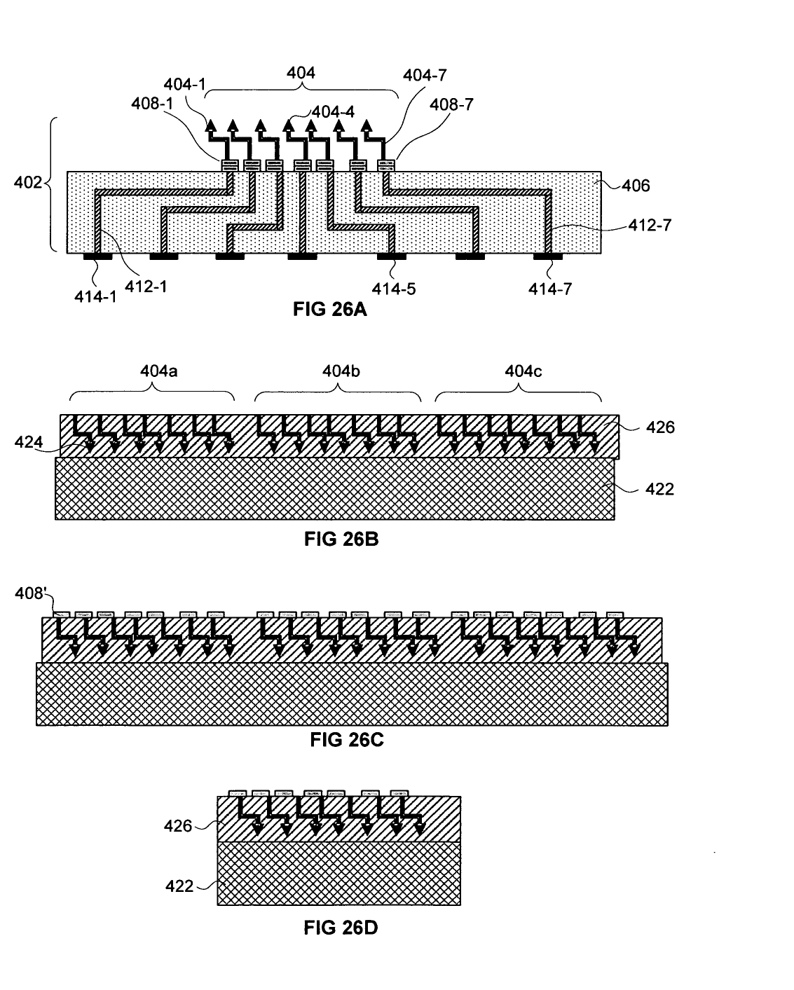

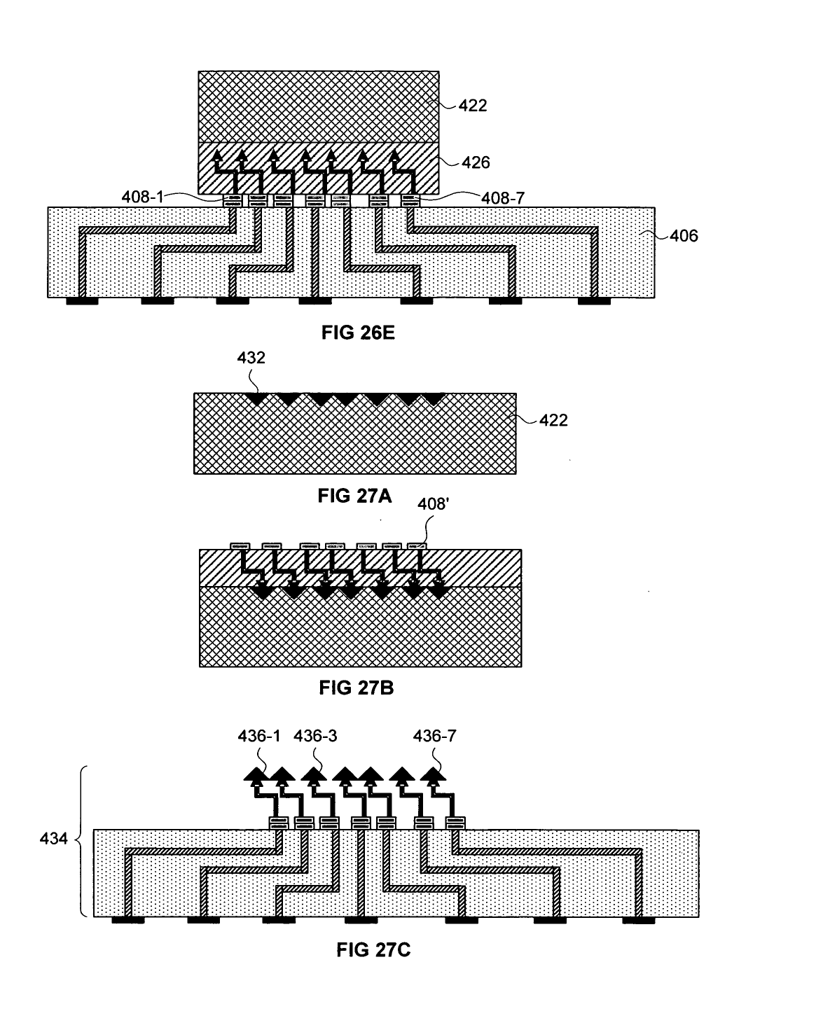

FIGS. 26A-26I depict schematic side views of various states of an example of a process for forming multiple, multilayer, multi-element probe arrays on a temporary substrate and then transferring and bonding at least a portion of the formed structures to a permanent substrate where the tips of the probe elements are molded in a patterned substrate, and diffusion bonding occurs prior to release but after transfer and bonding and where the process includes elements exemplified in the block diagrams of FIGS. 9, 15, and 23.

The process exemplified in FIGS. 26A-26E, includes the following primary operations:
1. Production of multiple probe arrays in an upside-down orientation on a suitable substrate (i.e. tips facing toward the substrate). In some implementations of the process the substrate may be a ceramic material or silicon. The probe arrays may be formed using electrochemical fabrication processes or the like.
2. Selective deposition of a bonding pad material. The bonding pad material for example may consist of gold, gold and nickel, or other metals or metal combinations. These bonding or joining pads may, for example, be formed by electroplating through openings in a patterned photoresist resist layer and will typically correspond, in number and to location, to the probe locations in the probe array and will also corresponding to joining pads on a permanent substrate to which the probe arrays will be transferred.
3. Dicing to separate the individual probe arrays.
4. Flip-chip bonding of the probe arrays to the permanent substrate. The substrate may be, for example, a polymeric or ceramic package with internal and/or external wiring structures that may be used to route signals from a component that the probe tips contact to other components that connect to the substrate. This operation typically involves the alignment and placement of the probe arrays onto selected locations on the substrate. Methods for bonding of the pads on the probe and permanent substrate are well known to those of skill in the art and may for example, include gold-to-gold diffusion bonding, bonding with gold-tin eutectic alloys, or with lead-tin solder. Diffusion bonding may, for example, occur with moderate heat (e.g. ˜400° C.) and pressure (e.g. ˜100 lbs/pad).
5. Dissolving the sacrificial metal component (e.g. Copper) of the layers of the array structure, for example, using enchants that are selective to sacrificial metal). During this operation, the temporary substrate is also be removed. This operation completes formation the fully assembled probe package.

FIG. 26A shows the state of the process after formation of a probe array package has been completed. The completed package 402 includes one or more electrochemically formed probe arrays 404 comprised of a plurality of probes 404-1 to 404-7. Each of the probe elements is bonded to a permanent substrate 406, which is also a functional substrate, by bonding pads 408-1 to 408-7. The substrate includes electrical lead lines 412-1 to 412-7 which in the present example extend to contact pads 414-1 to 414-7 which are located on the backside of the substrate.

In alternative embodiments, the substrate may include additional components such as capacitors, resistors, and inductors and/or shielding conductors that appropriately surround leads 412 so as to reduce signal loss and improve signal integrity.

FIG. 26B shows the state of the process after a temporary substrate 422 is supplied and multiple arrays 404a, 404b, and 404c are electrochemically formed with the tips 424 of the probes facing toward but not contacting the temporary substrate 422. Also as shown in FIG. 26B the probe structures are surrounded by a sacrificial material 426, for example, copper which was deposited during the layer-by-layer build up that was used to form the probe arrays. In some implementations the probe structures may be formed from nickel.

FIG. 26C shows the state of the process after bonding pads 408′ have been formed on the backsides of each of the probes in the probe arrays 404.

FIG. 26D shows the state of the process after probe arrays 404a, 404b, and 404c have been diced into individual array sections which include part of the temporary substrate 422, sacrificial material 426 along with the probes and bonding pads.

FIG. 26E shows the state of the process after an unreleased diced probe array as shown in FIG. 26D is bonded to a permanent substrate 406 via bonding pads 408-1 to 408-7. To complete the process the sacrificial material 426 is etched from the structures which causes removal of the sacrificial material as well as the diced portion of temporary substrate 422. The final probe array package that results from such a release is shown in FIG. 26A.

FIGS. 27A-27C depict schematic side views of various states of a process that forms enhanced probe tips on the probes of FIGS. 26A-26E.

If special probe tip configurations or materials are desired it may be possible to enhance the process discussed above in association with FIGS. 26A-26E by adding an initial operation. This initial operation involves the patterning of the temporary substrate with a pattern of holes having locations corresponding to the locations of the probes to be formed and having shapes corresponding to the desired shapes of the probe tips. These openings may then receive a desired probe tip material after which production of the probes via electrochemical fabrication operations may continue.

FIG. 27A shows the state of a process where holes in a temporary substrate 422 have been filled with a desired probe tip material 432 and the surface planarized.

FIG. 27B shows the state of the process after formation of the probes has been completed and bonding pad material 408′ added. The state of the process in FIG. 27B is analogous to the state of the process shown in FIG. 26D.

FIG. 27C shows the state of the process after probe array package 434 has been completed where the resulting probes have enhanced tips 436-1 to 436-7.

In some variations of the embodiments of FIGS. 26 and 27, the sacrificial material may include in whole or in part a polymeric material, such as a photo-resist or polyimide. In such cases, the polymeric material may be removed after bonding, for example, via plasma etching, chemical stripping, or the like. In still other variations if the polymeric material has been selectively located it may be retained as part of the final structure.

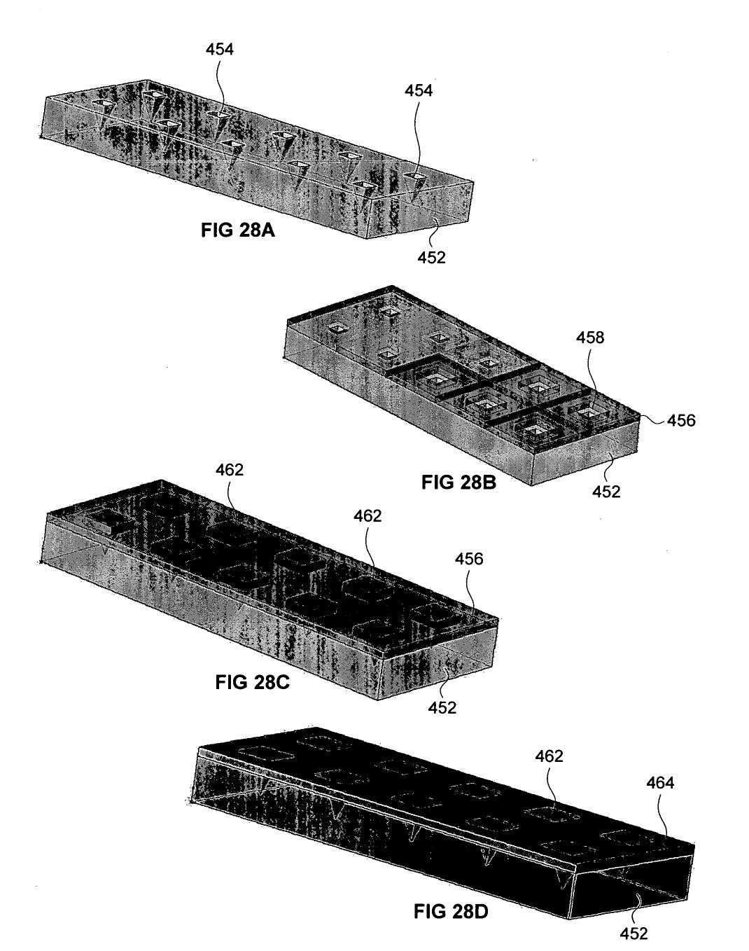

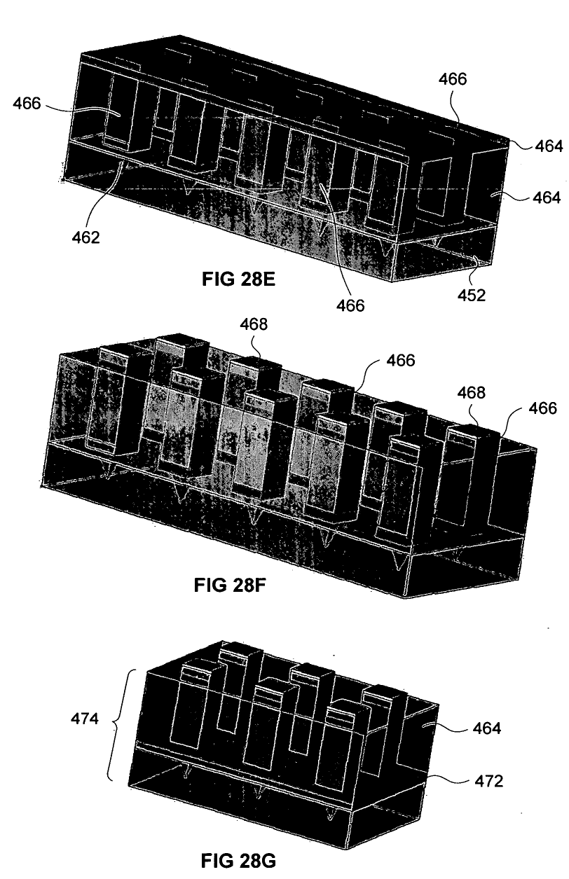

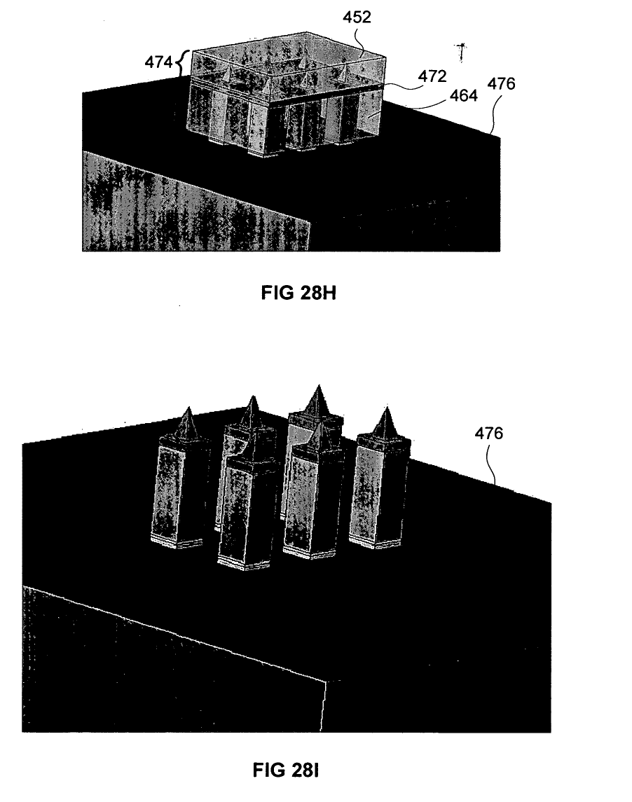

FIGS. 28A-28I depict schematic side views of various states of an example of a process for forming multilayer, multi-element probe arrays on a temporary substrate and then transferring and bonding the formed structures to a permanent substrate where the tips of the probe elements are molded in a patterned substrate of a tip material which may be different from a structural material, where prior to transfer individual probe arrays are analyzed for high yield probability and thereafter selected for use or non-use, and where the process includes elements exemplified in the block diagrams of FIGS. 9, 15, and 23.

FIG. 28A shows the state of the process after a temporary substrate 452 is selectively etched into to form voids 454 at locations where probe tips are to be formed wherein the voids are patterned to have the shape complimentary to that desired for the tips. In some implementations of the present process the substrate 452 may be silicon and sharp points or wedge shapes may be obtained by anisotropic etching whereas hemispheres or other rounded shapes may be obtained by isotropic etching.

FIG. 28B depicts the state of the process after a masking material 456 is applied to substrate 452 and is patterned to create openings 458 over the void regions 454 where probe tips are to be formed. In some implementations where necessary a seed layer may be applied to the substrate surface and into voids 454 prior to application and patterning of the masking material.

Additionally or alternatively a release layer material may be applied to the substrate surface and into the voids if necessary to aid in the release of the probes and probe tips from the substrate. In still other variations if desired the seed layer material may be applied after application of the masking material and the patterning of the masking material. Similarly if desired a release material may be applied over the masking material and into the voids in substrate 452.

FIG. 28C depicts the state of the process after a probe tip material 462 has been deposited into openings 458 in the masking material and voids 454 in the substrate. If necessary (for example, in embodiments where a seed layer or release layer overlays the masking material) the surface of tip material 462 and masking material 456 may be planarized to a height greater then that of the first layer thickness. If the planarization operation is used to remove seed layer or release layer material located above sacrificial material 456 then the height of planarization is still greater then the layer thickness or equal to the layer thickness but less then the thickness of the deposited masking material.

FIG. 28D depicts the state of the process after masking material 456 has been removed and a sacrificial material 464 has been deposited and the deposits of tip material and sacrificial material planed to a height of the first layer thickness. In a variation of the present process the masking material initially used may have overlaid voids 454 and sacrificial material may have been selectively deposited, the masking material removed and then the structural material plated, whereby the same result depicted in FIG. 28D would be obtained.

FIG. 28E depicts the state of the process after multiple layers of the probes have been formed out of sacrificial material 464 and structural material 466. In some implementations of the process, probe tip material 462 and structural material 466 may be one and the same material while in other implementations they may be different materials.

FIG. 28F depicts the state of the process after selective deposition of an additional layer of structural material 466 adds to the height of the probes and after a bonding pad material 468 is selectively deposited onto structural material 466. The selective deposition of the structural material and the bonding pad material may occur via a patterned mask where after deposition the masking material would be removed. In variations of the present process, instead of deposited the bonding pad material and possibly the additional layer of structural material, solder bumps may have alternatively been applied to the structural material.

FIG. 28G shows the state of the process after dicing of individual array sections occurs which results in array patterns of desired configuration that may be transferred to a permanent substrate. FIG. 28G also depicts a possible variation of the process as it indicates that one or more of the first layers 472 of sacrificial material 464 may be different from the sacrificial material used on subsequent layers.

FIG. 28H depicts the state of the process after the unreleased probe array 474 has been transferred and bonded to a permanent substrate 476.

FIG. 28I depicts the state of the process after temporary substrate 452 first formed layers 472 of sacrificial material 464 and remaining layers of sacrificial material 464 have been removed from the substrate to yield a final probe array attached to a permanent substrate. The released probe arrays attached to the permanent substrate may be considered a probe array package. It should be understood that though no specific probe structure configuration has been indicated in the present example as well as in the other examples set forth herein, a variety of probe configurations are possible including helical configurations, cantilever configurations and other possible configurations. Examples of such configurations are set forth in previously referenced and U.S. Patent Application No. 60/533,933 filed on Dec. 31, 2003. It should also be understood that in variations of this process other probe tip configurations are possible and other probe tip formation processes may be used.

Examples of other probe tip configurations and processes for forming such probe tips is set forth in previously referenced U.S. Patent Application No. 60/533,975. In still other variations of the present process the final probe array package may include multiple arrays of probe elements which may be separately or simultaneously attached to permanent substrate 476 and which in the event of a failure of a probe element may be replaced as an entire group or as individual probe arrays.

In some variations of the present process the permanent substrate may be a space transformer, a circuit board or even a programmable gate array. After formation of the package or more specifically after release of the probe tips from temporary substrate 452 it may be possible to modify the probe tip configurations to either sharpen them or to flatten them by, for example, use of chemical or electrochemical etching or deposition processes and the like.

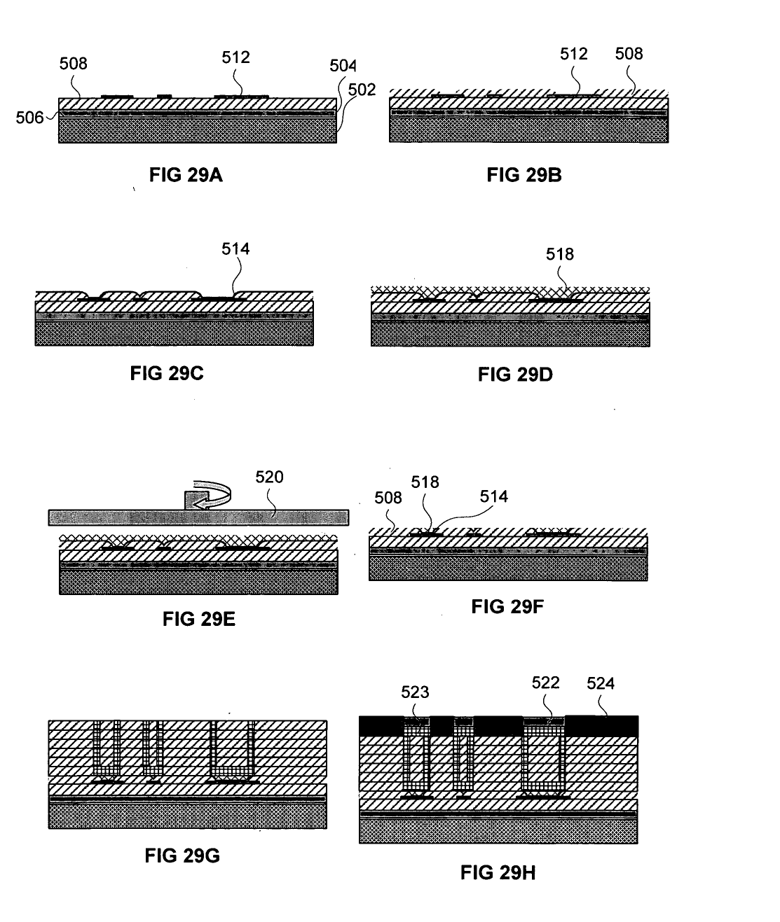

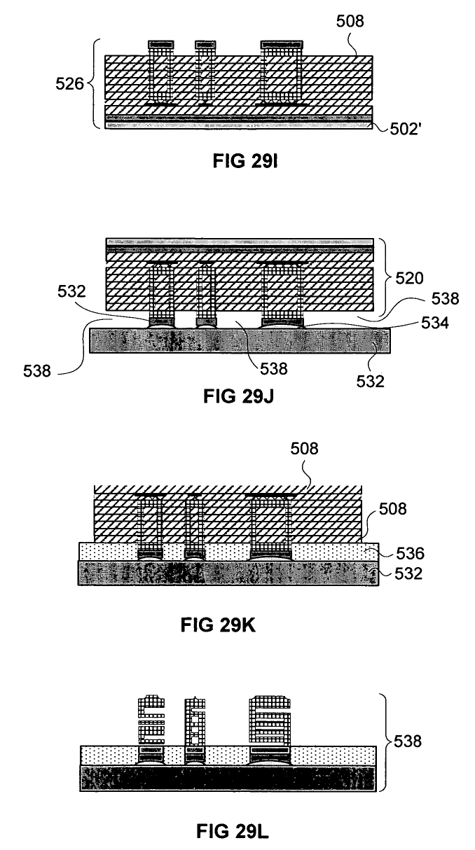

FIGS. 29A-29L depict schematic side views of various states of an example of a process for forming multilayer, multi-element probe arrays on a temporary substrate and then transferring and bonding the formed structures to a permanent substrate where the probe tips are shaped via a mold formed from sacrificial material, where the probe elements are separated from the temporary substrate by a meltable material, and where the process includes elements exemplified in the block diagrams of FIGS. 9, 15, and 22.

The process exemplified in FIGS. 29A-29L includes the following operations:
(1) Before the fabrication of the probes begins, a layer of a first metal 1 is deposited and planarized on the substrate surface. The first metal is chosen to have a melting point that is higher than the temperatures used in the various build operations (i.e. photolithography processes, deposition processes, etc.) but lower than the temperature required for any melt based bonding or adhesion material that is used (e.g. solder or tin). In some implementations, for example, the first material may be Indium.
(2) Once the first metal is deposited, a thick layer of a sacrificial material (e.g. Copper) is deposited and planarized also.
(3) On the planarized surface the building of a plurality of layers proceeds beginning with the formation of the tip, subsequent formation of probe bodies (e.g. helical spring structures, and the like) where the formation of each layer may include a structural material (e.g. nickel) and a sacrificial material (e.g. copper) or more than one of each.
(4) After formation of the last complete layer, additional structural material, of the same or of a different type, is selectively deposited to form bonding pads and above the bonding pads an adhesion or bonding material is added (e.g. tin or solder).
(5) Next the temporary substrate, on which the first material was deposited and on which the build was made, is sliced to thin it out to give it more of a wafer-like form, and individual dies are singulated.
(6) Next the dies are heat treated to enhance interlayer adhesion (e.g. by promoting low temperature diffusion bonding). During this process, the temperature may or may not rise to a point above the melting point of the first metal but if the melting point is reached it is believed that the surface tension of the molten first metal will keep the die-backing in place. In variations of the process the diffusion bonding operation may be delayed until after transfer to the permanent substrate has occurred.
(7) Next, individual die are located on (i.e. transferred to) the permanent substrate and bonded thereto. In some variations of the process an under fill material may be inserted between the permanent substrate and the probe elements prior to release of the sacrificial material. Use of such back fill may aid in protecting the adhesion material from negative interactions with the sacrificial material or etchants involved in removing the sacrificial material. In still other variations a intermediate material may have been added in place of the last layer or two of sacrificial material used in forming the probes.
(8) Next the die/package is treated to a thermal cycle in which the temperature is raised high enough to melt the first metal but nothing else. While at this temperature the temporary substrate is removed potentially along with some or all of the first metal. If necessary, another operation may be used to remove any residual first material (e.g. a planarization operation, a selective etching operation, or the like). These operations result in the exposing of the sacrificial material (e.g. Cu) on the built die that is now bonded to the permanent substrate.
(9) Finally, the sacrificial material is etched in a release process, so as to yield the completed probe package.

FIG. 29A shows the state of the process after a substrate 502 is covered with a seed layer 504 (if necessary), plated with a first metal 506, planarized, plated with a sacrificial material 508 (e.g. copper), planarized, then coated with a photoresist 512 which is patterned with plating stops in regions where probe tips are to be located.

FIG. 29B shows the state of the process after deposition of additional sacrificial material 508 which plates up from the previously deposited sacrificial material and also mushrooms over the patterned photoresist 512.

FIG. 29C shows the state of the process after a thin film of seed layer material 514 is deposited to bridge the dielectric portions of the plating stops. The seed layer material may be deposited, for example, by physical vapor deposition. In some variations of this process the deposition of the seed layer material may be preceded by deposition of an adhesion layer material.

FIG. 29D shows the state of the process after a blanket deposition of a tip material 518 occurs. In variations of the present process the tip material may be selectively deposited using an appropriately patterned mask and it may be the same material as a structural material 516 to be discussed shortly.

In still further variations of the present process, after deposition of seed layer 514 and prior to deposition of tip material 518 a blanket or selective deposition of a tip coating material or contact material may occur. This tip coating or contact material may be very thin compared to the overall height of the tip.

FIG. 29E shows the state of the process after a lapping plate 520 has been moved into place in order to lap and then possibly polish the blanket deposited tip material.

FIG. 29F shows the state of the process after planarization is completed thereby yielding a surface which consists of regions of sacrificial material 508, tip material 518, and seed layer material 514.

FIG. 29G shows the state of the process after a plurality of layers of sacrificial and conductive materials have been formed to build up the bulk of the probe structures. The fabrication of each of the plurality of layers may occur using an electrochemical deposition technique described herein elsewhere, using an electrochemical deposition technique described in one of the patents or patent applications incorporated herein by reference, or using some other technique for forming patterned layers of desired materials.

FIG. 29H shows the state of the process after a thick layer of a photoresist 524 (e.g. a cured liquid-based photoresist or a dry film photoresist) is applied and patterned, structural material 523 deposition occurs into the openings in the patterned photoresist to form bonding pads, and deposition of a bonding material 522 over those bonding pads occurs.

In some implementations of the present process the bonding pad material may be tin while in other embodiments a tin alloy may be used and/or some other material may be used.

FIG. 291 shows the state of the process after the patterned photoresist material 524 of FIG. 29H has been removed and after a slicing of substrate 502 thins it out to form substrate 502′ and after dicing (not distinguished) is performed to separate the structures into individual die.

Before or after dicing the formed structures may be subjected to a heat treatment which may enhance the interlayer adhesion so as to form a structure with more uniform properties.

FIG. 29J shows the state of the process after the dies 526 are flip-chip bonded to a permanent substrate 532 using bonding pad material 532 and a second bonding pad material 534 located on substrate 532.

FIG. 29K shows the state of the process after a dielectric underfill material is made to fill voids 538 between the substrate 532 and sacrificial material 508 and after heating of the structures occurs to a temperature sufficient to melt the first metal, and separation of the structures from the temporary substrate 502′ occurs.

FIG. 29L shows the state of the process after sacrificial material 508 and plate stop material 512 are removed, thereby releasing the completed probes and forming probe packages 538.

Many additional variations of the above process are possible and will be understood by those of skill in the art upon review of the teachings herein and those incorporated herein by reference.

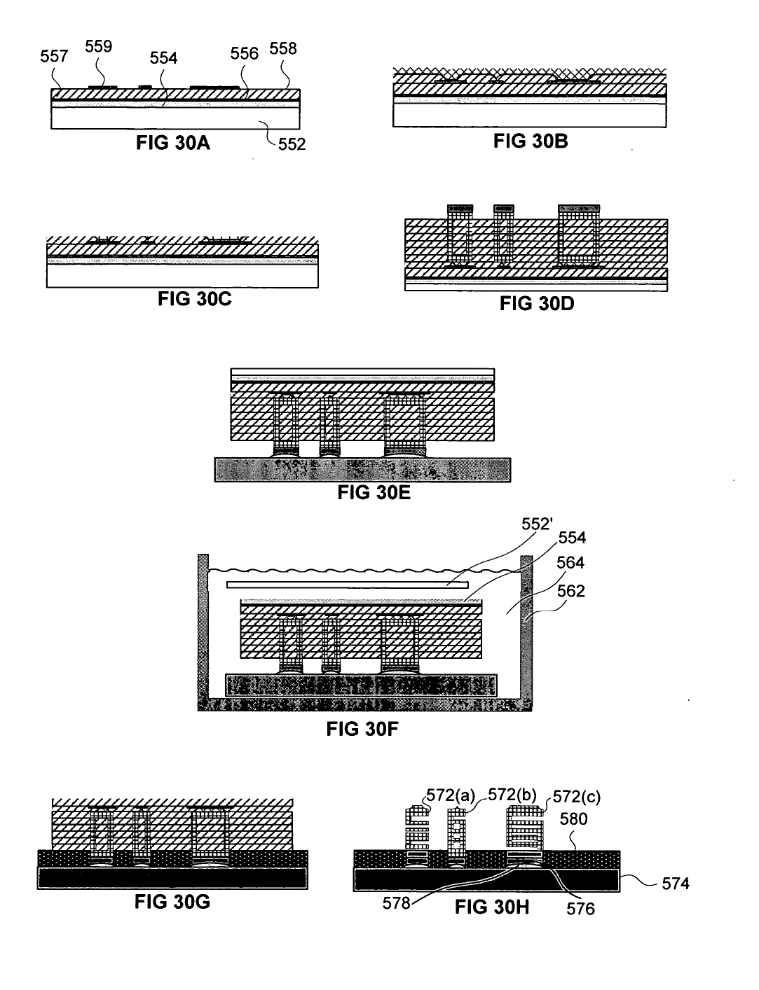

FIGS. 30A-30H depict schematic side views of various states of an example of a process for forming multilayer, multi-element probe arrays on a temporary substrate which is similar to that shown in FIGS. 29A-29L with the exception that the first metal is replaced by a dielectric material.

The process exemplified in FIGS. 30A-30H includes the following operations:
(1) Coat a substrate (e.g. a glass material or other material) with a first dielectric material that may be released from between a temporary substrate and the layers of materials deposited to build up the structures (e.g. the dielectric material may be a polyimide material). If desired the dielectric may be spun on, cured, and adhered to the surface on the substrate.
(2) Apply a seed layer over the dielectric material for electrical connection for electroplating.
(3) Deposit (e.g. by electroplating) a thick layer of a sacrificial material (e.g. copper) and then lap and polish it.
(4) Form the tips, probe-bodies, bonding pads, and bumps in a manner similar to that described above in association with FIGS. 29A-29L.
(5) Slice and dice the structures and temporary substrate.
(6) Mount and bond the die to a permanent substrate as described in association with FIGS. 29A-29L.
(7) Release the temporary substrate. For example, if the first dielectric is polyimide and the temporary substrate is glass, the structure and temporary substrate may be immersed in boiling water. The water will affect the adhesion of the polyimide to the glass and will cause the polyimide to delaminate. This will effectively allow removal of the glass and then the polyimide layer may be either manually peeled off or etched off using plasma or wet etch. This will result in exposure of the sacrificial material.
(8) The sacrificial material may then be removed by etching to release the structure.

FIG. 30A depicts the state of the process after a temporary substrate 552 (e.g. formed of glass) is coated with a dielectric material 554 (e.g. polyimide), which is in turn coated with a seed layer material 556 and which in turn is coated with a thick layer of sacrificial material 557 (e.g. electroplated copper) which in turn is coated with a patterned photoresist material 559 in regions where probe tips are to be formed.

FIG. 30B depicts the state of the process which is analogous to the state depicted in FIG. 29D.

FIG. 30C depicts the state of the process which is analogous to the state depicted in FIG. 29F.

FIG. 30D depicts the state of the process which is analogous to that shown in FIG. 29I, while FIG. 30E depicts the state of the process which is analogous to that shown in FIG. 29J.

FIG. 30F depicts the state of the process after thinned temporary substrate 552 is separated from the dielectric coating 554. In the case of a glass substrate and a polyimide dielectric material, the separation may occur by immersing the structure in a tank 562 of boiling water 564 as shown.

FIG. 30G depicts the state of the process after the dielectric material has been removed, for example, by peeling or plasma- or wet-etching and after an underfill material has been located between exposed portions of the permanent substrate and the sacrificial material used in forming the layers of the structure.

FIG. 30H shows the state of the process after removal of the sacrificial material leaving behind probe elements 572(a)-572(c) which are adhered to a permanent substrate 574 via bonding materials 576 and 578 and potentially via underfill material 580.

A next embodiment of the invention relates to methods of making microprobes using electrochemical fabrication techniques, including fabrication (with tips), transfer and bonding to a space transformer or other substrate, and (optional) coating. As discussed above, various methods for making tip geometries are available and set forth in the patent application No. 60/533,975 which is incorporated herein by reference. For simplicity, in the embodiment to follow a single tip fabrication approach has been selected but those of skill in the art will understand that in variations of the embodiment other fabrication techniques may be used. In particular, in the embodiment to follow an approach based on the ‘mushrooming’ of sacrificial material over resist features is used to define the tip geometry.

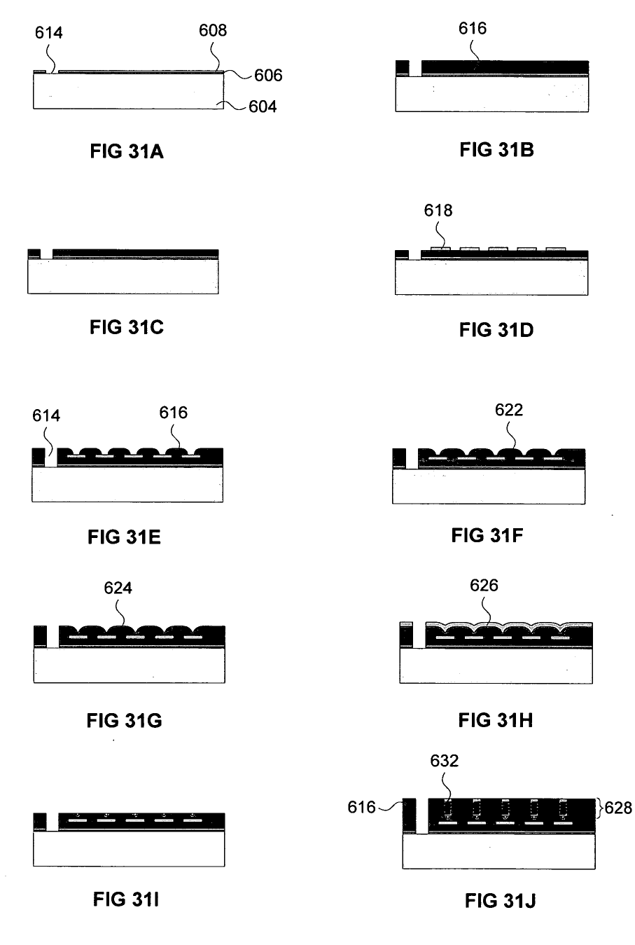

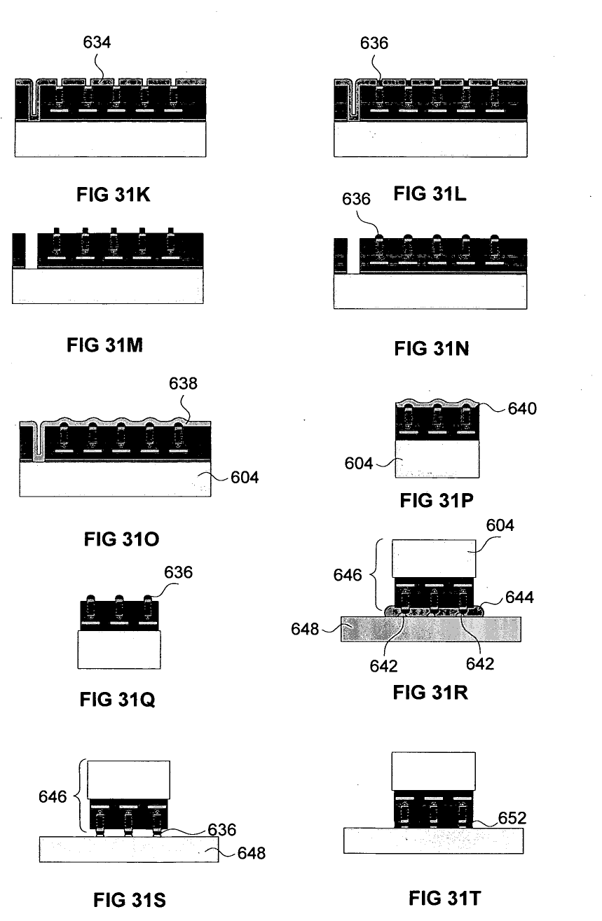

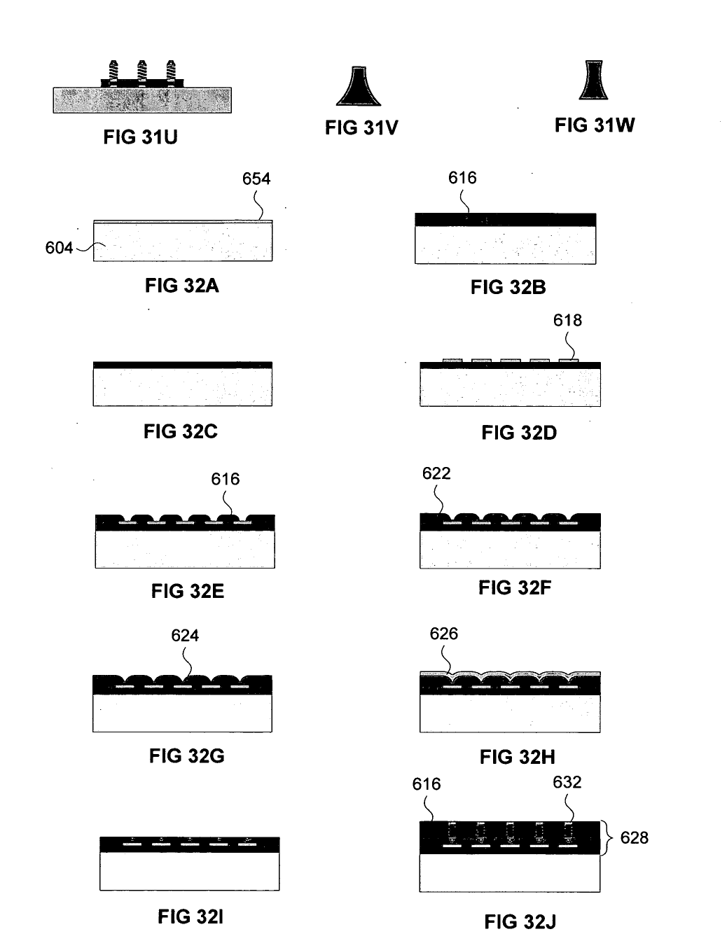

FIGS. 31A-31W outline the operations associated with a sample process which does not involve coating of probes. In FIG. 31A, a temporary wafer 604 is shown, here assumed to be dielectric such as alumina that is coated with seed 608 and adhesion 606 layers. These metallization layers are not present in three (e.g., 120° apart) areas (e.g., due to etching or lift-off) to expose the wafer surface and thus form non-plating endpoint detection pads 614. In FIG. 31B, thick sacrificial material 616 (e.g., Cu) has been plated and in FIG. 31C, this ‘release’ layer has been planarized. In FIG. 31D, thin photoresist 618 (or other dielectric) has been patterned to form insulating structures over which sacrificial material can mushroom to form tip geometries and in FIG. 31E, Cu has been mushroomed over these by plating for a controlled time to form the desired tip geometries. In FIG. 31F, Cu 622 (normally after depositing an adhesion layer, preferably Ti—W) is deposited by sputtering or evaporation in order to make the exposed resist upper surface conductive, and the Cu film has been removed (e.g., by etching or by removal of a masking material which prevented deposition) from the end-pointing pads 614. It should be noted that if the tip coating material 624 applied in the next step is applied by PVD (i.e., by sputtering or evaporation) then this step may be omitted. This step may also be omitted if only a single tip material will be applied in the subsequent steps, or if the first layer of a 2-layer tip is relatively thick; in both cases, heavy plating of the tip material may cause sufficient mushrooming from the sidewalls of the Cu to allow plating over the resist without need for a seed layer. Finally, this step may possibly be omitted if the ‘drilling’ etching technique already disclosed by Kieun Kim has been used to perforate the resist where exposed through the Cu, and thus enable contact with the underlying conductive material.

Subsequent figures assume that the tips are in fact formed from two different materials. In FIG. 31G, the tip coating material 624 (e.g., Rh) is deposited (e.g., by electrodeposition). This deposit may be fairly thin (e.g., 1-3 μm) to minimize stress-related delamination or cracking in the tip coating material (not uncommon with platinum-group metals). Note that in some cases, tips can be fabricated made entirely of the tip coating material and no backing material is needed. However, for tip coatings that are too soft (e.g., Au) or which have too much residual stress (e.g., possibly Re or Rh) as deposited, a thin coating would preferably be used, backed by another material. In FIG. 31H, a secondary ‘backing’ tip material 626 has been plated to form the bulk of the tip, and in FIG. 31I, the wafer has been planarized.

In FIG. 31J, multiple layers 628 of structural material (e.g., Ni) have been deposited to form the probes. It is assumed that a probe base 632 is fabricated as part of the probe (i.e., the topmost (eventually bottommost) layer(s); this might have the form of a disk whose diameter is similar to that of the probe. In FIG. 31K, thick resist 634 is deposited and patterned, and in FIG. 31L solder 636 (e.g., Sn—Pb, but also pure Sn) or similar material is plated into features of the resist. If a probe base has not been formed, Ni can be plated before plating the solder to form a base. The base, no matter how it is formed, provides a wettable pad for the solder ball and a stable foundation for the probe.

In FIG. 31M, the resist is stripped and in FIG. 31N, the solder 636 is reflowed to form a bump. Note that the reflow may be performed later (once the wafer is singulated), and reflow is not strictly necessary prior to bonding (see FIGS. 1R-1S). It should also be noted that the etch-back operation shown in FIG. 31Q may need to be performed prior to reflow (or alternatively, there can be two etch-back operations) in order to recess the Cu surface below the Ni such that the solder cannot wick out over the Cu surface once molten.

In FIG. 31O, a protective coating 638 has been applied to the wafer 604 prior to dicing, and in FIG. 31P, the wafer 604 can been diced. The dicing operation may leave a burr 640 on the Cu surface that can interfere with subsequent bonding. By judicious choice of protective coating (preferably a hard material such as a soluble wax like Crystalbond 509 made by Aremco), the size of this burr 640 can be kept small. In FIG. 31Q, an etch-back of the Cu has been performed. This etch-back serves several purposes: a) removing the burr; b) recessing the Cu surface below that of the solder. The latter is done for two reasons: 1) as noted above, to eliminate the risk of solder wicking out across the Cu and shorting together neighboring probes; 2) to separate the solder from the Cu, allowing the former to be embedded in an underfill that protects it during Cu release.

If a permanent underfill will be used, the etch-back is preferably done to an extent that leaves the Cu surface no lower than the bottom of the probe base, since the Cu surface will define the top of the underfill (see FIG. 31T). If no underfill or only a temporary underfill will be used, the Cu can be etched further, which facilitates and reduces the time required for the full release later; in this regard, the release may be continued much further than shown here (limited only by the desire to a) hold all the probes in good alignment until bonded; b) minimize the risk of damage to the probes until bonded); c) prevent the underfill polymer (if used) from enveloping the probes and interfering with their compliance (indeed, if the gap is too large the underfill may not properly wick in due to reduced capillary pressure). In lieu of, or in addition to, etch-back to remove the burr, electropolishing or mechanical processing (sanding, lapping, polishing, sandblasting) may be employed.

In addition to the etch-back in FIG. 31Q, diffusion bonding has been performed (not shown), either before or after etch-back. The latter is preferable since there is less Cu and thus less risk of stress due to differences in CTE between Cu and other materials. Moreover, with the Cu already recessed relative to the Ni due to the etch, the solder bumps on the surface are more likely to remain in place during the reflow that will occur during diffusion bonding. It should be noted that since the bumps will likely reflow during diffusion bonding (e.g., at 250° C.) anyway, the earlier step to reflow them (FIG. 31N) may be bypassed. It should also be noted that it may be possible and desirable to diffusion bond at the wafer level (e.g., after FIG. 31J), though the stresses may be too large to allow this unless the wafer is first ‘scored’ by partially dicing through it (e.g., cutting through all deposited layers but only slightly into the temporary wafer). It should also be noted that if the space transformer can tolerate the temperature, it may be possible to do diffusion bonding after the step of FIG. 31S or simultaneous with it.

In FIG. 31R, the die 646 has been flipped and aligned roughly (e.g., to +/−5 μm) to the bumps 642 on a space transformer, IC package, or other substrate 648 (e.g., a PC board). Note that multiple die fabricated in close proximity on the temporary wafer 604 can thus be dispersed widely across a much larger substrate, e.g., for making probe cards for memory testing (characterized by relatively low probe density but large area). The alignment may be performed by equipment known to the art for die bonding such as that manufactured by Palomar Technologies (e.g., model 6500) or Semiconductor Equipment Corporation (e.g., System 850 with a hot gas heater stage). Such equipment may use multiple cameras, for example, to image the die and space transformer when face-to-face, align them together, and heat them to perform a bond. The space transformer is assumed to include bumps or other isolated metallic contacts as shown. If these contacts are composed of solder, it may not be necessary to apply additional solder to the probe base as already described, in that the solder from the space transformer 648 can directly bond to the probe base. A liquid or paste flux 644 has been applied to either or both the die 646 or the space transformer 648 to a) temporarily adhere the two together well enough to retain alignment until bonded; b) minimize oxide formation which can interfere with good bonding. To help with the latter, an ‘active’ flux may be preferable.

In FIG. 31S, the solder 636 has been reflowed, self-aligning the die 646, and the flux 644 has been removed by an appropriate solvent. In FIG. 31T, an underfill material 652 has been wicked in to fill the space under the die. This could be a material such as an epoxy or flip-chip underfill if a permanent underfill is desired to provide additional strength to the final device. Or the underfill may be a material such as a wax (e.g., Crystalbond 509), lacquer, etc. which is removed after release of the Cu. In either case, the use of an underfill is generally needed in order to allow the Cu to be etched without damage to the solder, since the latter may tend to be etched in the Cu etchant, possibly acting as a sacrificial anode. It should be noted that the etchback step shown in FIG. 31Q may be difficult to accomplish due to a tendency for the exposed solder to etch instead of the Cu; this may be handled by 1) temporarily coating the solder with a protective material (e.g., by dipping the solder into a thin layer of polymer spin coated onto a flat plate); 2) by coating the solder with Au (e.g., immersion Au through dipping).

An alternative to the underfill discussed above is the use of a coating (e.g., electroless or immersion Au) at the stage shown in FIG. 31S, in order to coat the solder 636, on the die 646 and/or the space transformer 648 and protect it against etching by the Cu etchant. A thin layer of this coating may also be deposited on the lower surface of the Cu, but since this bridges the probes without any mechanical support once the Cu is etched, it should be easily removed (e.g., by ultrasonic agitation).

In FIG. 31U the die 646 has been fully released from Cu. Note that keeping the probes embedded at least partially in Cu up until now provides great robustness for handling and keeps all the structures in perfect 6-axis alignment during bonding, etc. During this process, the Cu-enveloped photoresist features patterned earlier would typically fall away or become dissolved. If desired, the release process can be stopped and a photoresist stripper used once the resist is exposed, then the release continued. At this point if desired the probes can be etched (e.g., with a Ni etchant, possibly selective to other materials such as tip materials) to remove any extraneous material. Another effect of this etchant might be to remove the ‘flared’ region from the probe tip. A tip produced through the ‘mushrooming’ method described above should have the appearance shown in FIG. 31V. However, tips may actually be wider at the top (FIG. 31W) than partway between top and bottom, causing a flaring effect that widens the effective contact area between tip and probed surface. The etchant can also round the corners of the tip if that is desirable.

It should be noted that an alternative to bonding the die to the space transformer using solder would be to bond it using thermocompression bonding, e.g., of Au. In this case, one would have plate Au vs. solder in FIG. 31L, and the space transformer contacts would also be Au-coated. With the two Au surfaces in contact, heat and pressure would be applied to bond the die to the space transformer. In this case, it may not be necessary to use any underfill since there is no solder to be protected during Cu etching (Au normally would not be attacked by the Cu etchant).

As a further extension to what is shown in FIGS. 31A-31W, one can fabricate and transfer/bond other structures and devices than probes which are useful in the final probe card, also to the space transformer. Examples of these include interconnects (traces, microstrip, coaxial transmission lines), switches, capacitors, resistors, and inductors.

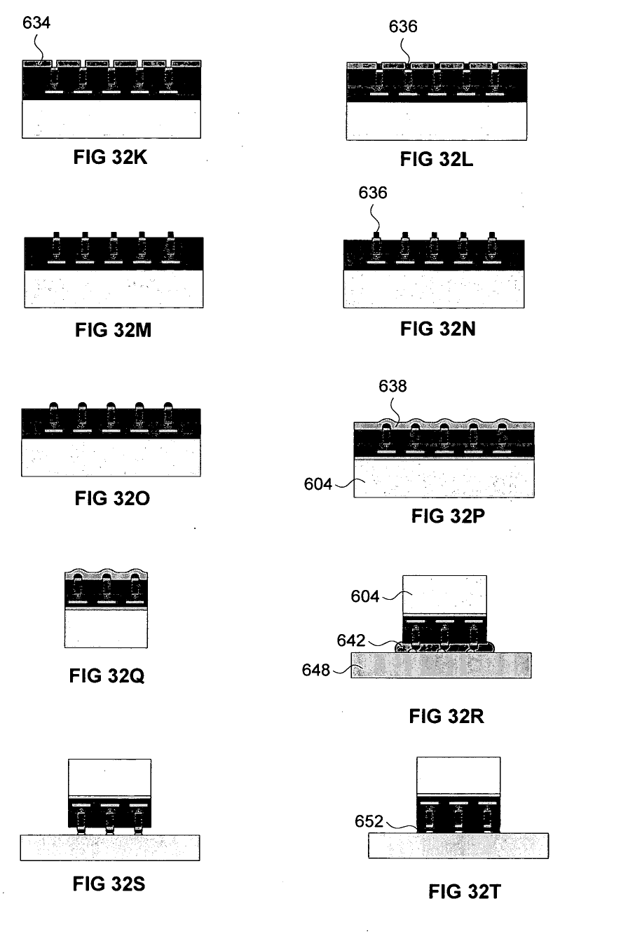

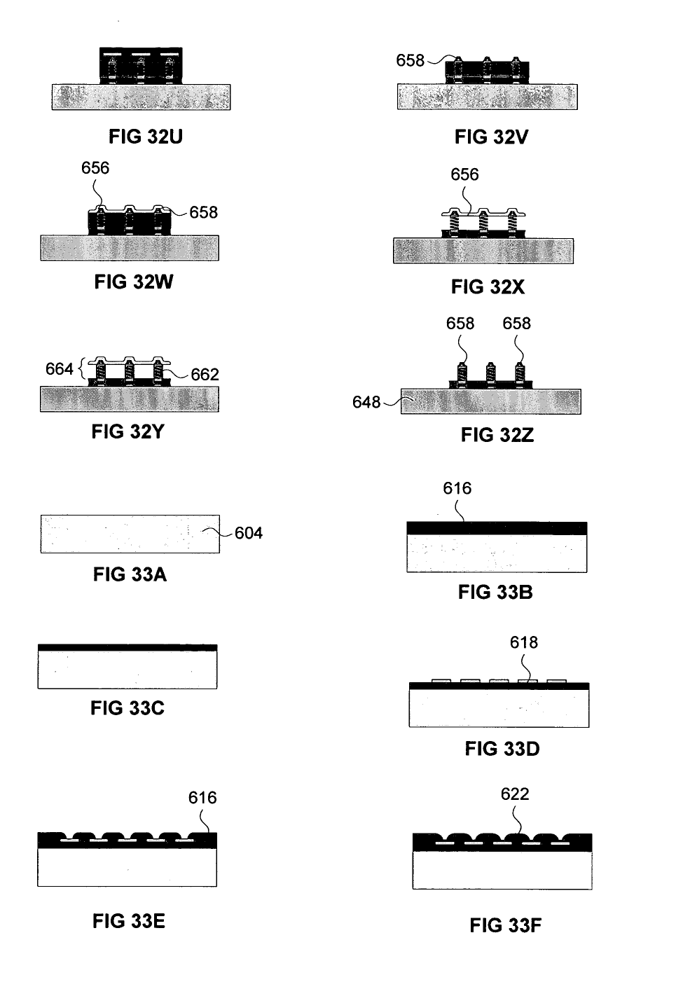

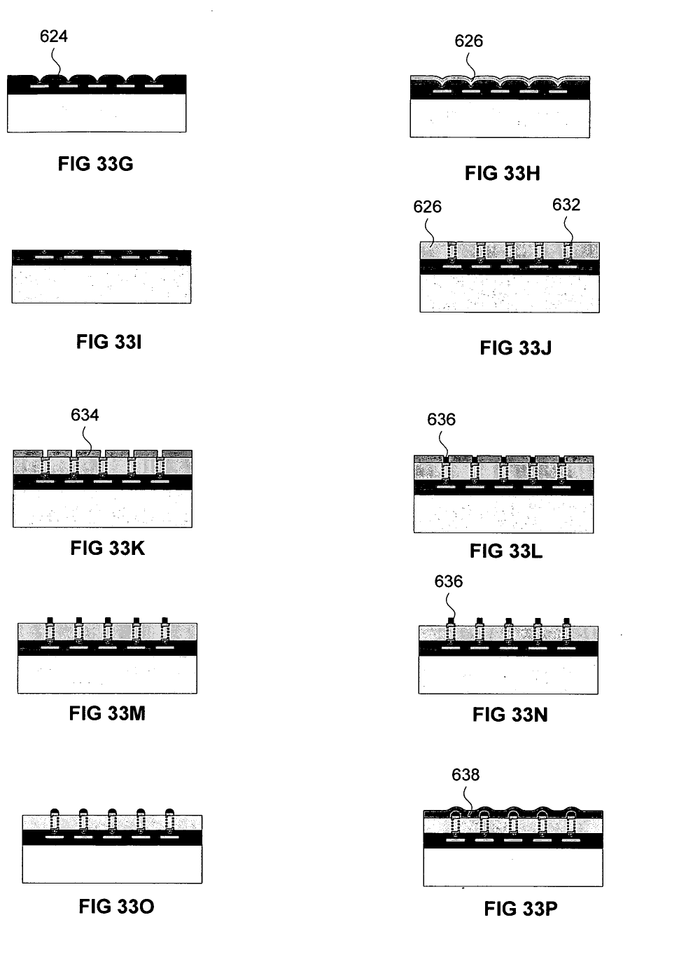

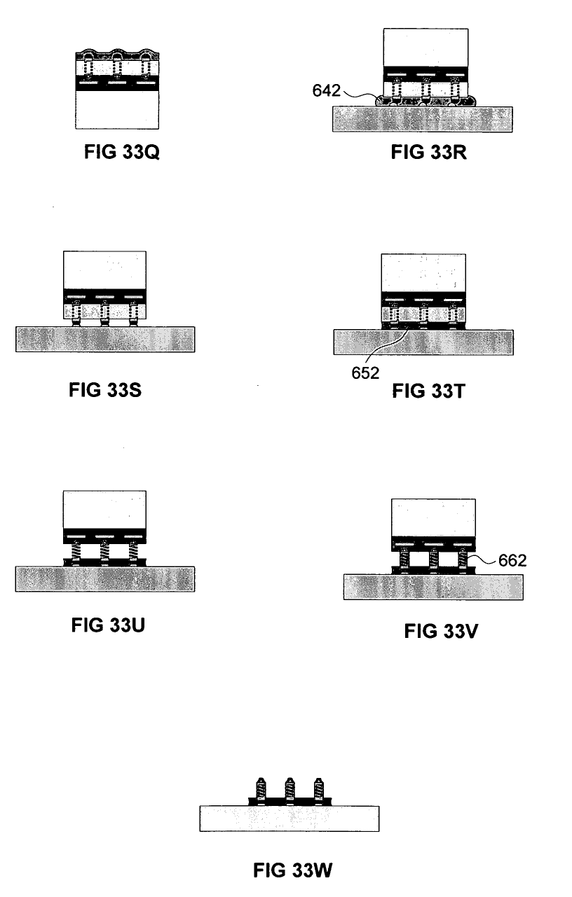

FIGS. 32A-32Z depict schematic side views of various states of an example process which is similar to that of FIGS. 31A-31W, but which additionally involves coating of the probe (e.g., Au or Cu coating to decrease probe resistance, or Ni coating (e.g., of a Cu or Au probe) to increase probe mechanical stiffness. It is assumed that whatever coating is applied to the probes, it is not desired to apply this same coating to the tips. Achieving a coating on the sides without coating the tips is challenging, but the current embodiment provides an example of such a solution.

FIGS. 32A-32T are analogous with FIGS. 31A-31T (note that the dicing burr is not shown on FIG. 32Q). However, a release layer 654 (FIG. 32A) is provided in the process flow in order to allow for partial Cu release starting with the tips of the probes, allowing them to be coated 656 as shown in FIG. 32W. This release layer 654 is preferably a conductive material (e.g., In) that can be melted to release the temporary build wafer. In FIG. 32U the release layer 654 has been removed (after melting, there may be a residue of this layer that needs to be removed by etching, polishing/lapping, etc.) In FIG. 32V, the Cu has been etched partially to expose the tips 658. In FIG. 32W, the tips 658 are then coated 656 with a polymer (e.g., Cu etchant-compatible photoresist (such as Shipley BPR 100) or wax (e.g., Crystalbond)) by dipping, spin coating, spraying, or other suitable methods. The tips can also be coated with a non-polymeric material so long as the coating 656 applied in FIG. 32X will either not deposit on the material, will deposit non-adherently, or will come off when the material is removed (e.g., a lift-off type process).

In FIG. 32X the Cu has been etched out from around the probes. Note that because of the presence of the polymer, the etching takes place only from the sides). In FIG. 32Y the probes 664 have been coated 662 (e.g., by electroless means, or possibly by chemical vapor deposition, PVD, or electroplating). Finally, in FIG. 32Z the polymer has been removed from the tips 658, leaving them free of the coating.

In order to improve the bonding of the coating to the probes, it is desirable to heat treat after the coating is deposited (not shown). If diffusion bonding has not yet been performed prior to coating, then diffusion bonding and coating bonding may be performed simultaneously, as long as the space transformer 648 can tolerate the temperature required for diffusion bonding (which may be higher than that required to enhance bonding of the coating).

A preferred embodiment (not shown) that is a variation of the embodiment shown in FIG. 32 is as follows: Rather than apply the polymer as shown in FIG. 32W to the entire top surface, the polymer is applied only to the tips, leaving polymer-free areas between probes. One way of accomplishing this is to spin coat a thin layer of polymer onto a flat plate and then carefully bring the tips into contact with this layer and then pull them away. This method can be implemented at any time before the coating step shown in FIG. 32Y, thus it is not necessary to first do a partial release as shown in FIG. 32V (and thus it is not necessary to use a release layer which allows the temporary wafer to be removed). The advantages of coating just the tips and not forming a continuous film of polymer as shown in FIG. 32X are 1) if the Cu etching has not yet been done, the etching can proceed from the top down as well as from the sides in; 2) there is no continuous film to interfere with the coating process (e.g., in the case of electroless deposition, to reduce the exposure of the probes to the bath and thus reduce agitation).

In another embodiment (not shown), the coating is allowed to deposit over the tips, but is then removed by one of several means from the tips, such as: 1) protecting the remainder of the probes (e.g., by application of a wax) and then chemically etching the coating off the tips; 2) touching the tips to a plate covered with a thin layer of an etchant that attacks the coating material (possibly made viscous so that it does not easily wick up the sides of the probe and remove the coating there as well); 3) mechanical removal of the coating material from the tips (e.g., by polishing or lapping).

In another embodiment (not shown), deposition of coating onto the tips is prevented by depositing a material that cannot be plated by the coating (or to which the coating has low adhesion) before the tip is formed, e.g., in lieu of the PVD Cu that is deposited in FIG. 32F. This material is preferably conductive, but need not strictly be; if one uses an insulating material and then PVD deposits a seed layer (e.g., Cu) or PVD deposits the tip material directly, then further processing should proceed without difficulties. There will be after planarization (FIG. 321) a ring of insulating material associated with each tip that separates the metal inside the ring from that outside it; however, once the first layer is plated over this planarized surface, the plating should mushroom over the thin insulating ring and reach the inside metal, quickly coating it.

In a related embodiment, before depositing tip material one deposits a Cu etch barrier material (e.g., Ni), followed by thin Cu, followed by the tip material of interest: when the final release is performed in FIG. 32X, the thin layer of Cu coating the tip will not fully etch, since it is covered with Ni. Thus when the coating is applied in FIG. 32Y, the coating will coat the Ni over the tip but not the tip itself. With additional Cu etching, the Cu over the tip will eventually be etched, releasing the Ni ‘cap’ (now plated with the coating as well) and exposing the desired tip material.

In another embodiment, the temporary wafer 604 may be released from the probe build before transfer/bonding of the probes to the space transformer 648 (FIG. 32R), vs. after this as shown (FIG. 32U). Since the probes are encased in sacrificial material the entire structure (typically several hundreds of microns thick) may be self-supporting and the temporary wafer 604 dispensed with earlier.

FIGS. 33A-33T depict schematic side views of various states of an example process which is similar to that of FIGS. 32A-32T except that instead of using two sacrificial materials 626 and 616, only one sacrificial material 626 was used.

FIG. 33U illustrates the removal of sacrificial material 626.

In FIG. 33V a coating is applied to the probes.

The temporary substrate 604 is removed in FIG. 33W as well as the remaining sacrificial material 626 and photoresist 618.

Various other embodiments of the present invention exist. Some of these embodiments may be based on a combination of the teachings herein with various teachings incorporated herein by reference. Some embodiments may not use any blanket deposition process and/or they may not use a planarization process. Some embodiments may involve the selective deposition of a plurality of different materials on a single layer or on different layers. Some embodiments may use selective deposition processes or blanket deposition processes on some layers that are not electrodeposition processes. Some embodiments may use nickel as a structural material while other embodiments may use different materials. Some embodiments may use copper as the structural material with or without a sacrificial material. Some embodiments may remove a sacrificial material while other embodiments may not. Some embodiments may employ mask based selective etching operations in conjunction with blanket deposition operations. Some embodiments may form structures on a layer-by-layer base but deviate from a strict planar layer on planar layer build up process in favor of a process that interlacing material between the layers. Such alternating build processes are disclosed in U.S. application Ser. No. 10/434,519, filed on May 7, 2003, entitled Methods of and Apparatus for Electrochemically Fabricating Structures Via Interlaced Layers or Via Selective Etching and Filling of Voids which is herein incorporated by reference as if set forth in full.

In view of the teachings herein, many further embodiments, alternatives in design and uses of the embodiments of the instant invention will be apparent to those of skill in the art. As such, it is not intended that the invention be limited to the particular illustrative embodiments, alternatives, and uses described above but instead that it be solely limited by the claims presented hereafter.

1. A method for fabricating a microprobe array, comprising:
fabricating at least a portion of each of a plurality of probes on a temporary substrate;
transferring the probes from the temporary substrate to a permanent substrate.

2. The method of claim 1, wherein at least selected groups of probes on the temporary substrate have a spatial relationship that is to be maintained when they are transferred to the permanent substrate.

3. The method of claim 2 wherein a selectively located adhesion material is located on the permanent substrate in locations where probes of a selected group are to be attached.

4. The method of claim 2 wherein a selectively located adhesion material is located on an end of the probes after they are formed on the temporary substrate and thereafter the probes are transferred to the permanent substrate.

5. The method of claim 2 wherein a selectively located adhesion material is located on the permanent substrate in locations where probes of a selected group are to be attached and wherein a selectively located adhesion material is located on an end of the probes after they are formed on the temporary substrate and thereafter the probes are transferred to the permanent substrate.

6. The method of claim 1, wherein transfer to the permanent substrate occurs prior to release of the probes from the temporary substrate.

7. The method of claim 6, wherein transfer to the permanent substrate occurs after release of the probes from at least a portion of any sacrificial material that surrounded them during formation.

8. The method of claim 6, wherein transfer to the permanent substrate occurs prior to release of the probes from any sacrificial material that surrounded them during formation.

9. The method of claim 1, wherein transfer to the permanent substrate occurs after release of the probes from the temporary substrate.

10. The method of claim 9, wherein transfer to the permanent substrate occurs prior to release of the probes from any sacrificial material that surrounded them during formation.

11. The method of claim 1, wherein transfer to the permanent substrate occurs after release of the probes from at least a portion of any sacrificial material that surrounded them during formation.

12. The method of claim 1, wherein the transferring of the probes from the temporary substrate to a permanent substrate, comprises:
a. transferring the probes from a temporary substrate to a second temporary substrate, and then
b. transferring the probes from the second temporary substrate to the permanent substrate.

13. The method of claim 1, wherein the formation of the probes on the temporary substrate result in only partial formation of the probes and wherein completion of the formation of the probes occurs while the probes are attached to the permanent substrate.

14. The method of claim 1, wherein prior to transferring the probes to the permanent substrate the probes undergo a heat treatment process capable of enhancing adhesion between layers of material from which the probes are formed.

15. The method of claim 1, wherein after transferring the probes to the permanent substrate the probes undergo a heat treatment process capable of enhancing adhesion between layers of material from which the probes are formed.

16. The method of claim 1, wherein during transferring of the probes to the permanent substrate the probes are embedded in a conductive sacrificial material which is removed after transfer.

17. A method for fabricating a microprobe, comprising:
fabricating at least a portion of the microprobe on a temporary substrate;
transferring the microprobe from the temporary substrate to a permanent substrate.

18. A method for fabricating a compliant electrical contact element array, comprising:
fabricating at least a portion of the compliant electrical contact elements on a temporary substrate;
transferring the compliant electrical contact elements from the temporary substrate to a permanent substrate.

19. A method for fabricating a compliant electrical contact element adhered to a permanent substrate, comprising:
fabricating at least a portion of the compliant electrical contact element on a temporary substrate;
transferring the compliant electrical contact element from the temporary substrate to a permanent substrate.
